(19) United States
(12) Patent Application Publication
(10) Pub. No.: US 2024/0219359 A1
(43) Pub. Date: Jul. 4, 2024

(54) METHOD FOR INSPECTING TREATMENT LIQUID AND METHOD FOR PRODUCING TREATMENT LIQUID

(71) Applicant: FUJIFILM Corporation, Tokyo (JP)

(72) Inventors: Tetsuya SHIMIZU, Haibara-gun (JP); Michihiro SHIRAKAWA, Haibara-gun (JP); Satomi TAKAHASHI, Haibara-gun (JP)

(73) Assignee: FUJIFILM Corporation, Tokyo (JP)

(21) Appl. No.: 18/603,775

(22) Filed: Mar. 13, 2024

Related U.S. Application Data
(63) Continuation of application No. PCT/JP22/34227, filed on Sep. 13, 2022.

(30) Foreign Application Priority Data
Sep. 21, 2021 (JP) 2021-152966

(51) Int. Cl. G01N 30/72; G01N 30/02; G03F 7/32

(52) U.S. Cl. CPC G01N 30/7206; G03F 7/32; G01N 2030/025

(57) ABSTRACT

An object of the present invention is to provide a method for inspecting a treatment liquid to determine whether the treatment liquid, when used as a developer or a rinsing liquid, allows formation of a resist pattern with reduced variation in line width. Another object of the present invention is to provide a method for producing a treatment liquid.

The method for inspecting a treatment liquid according to the present invention is a method for inspecting a treatment liquid including an aliphatic hydrocarbon solvent and has a step A1 of acquiring measurement data of a content of an acid component in the treatment liquid, the acid component being at least one selected from the group consisting of carboxylic acids having a hydrocarbon group having 1 to 3 carbon atoms and formic acid, and a step A2 of determining whether the measurement data acquired in the step A1 falls within a preset allowable range.

### CROSS-REFERENCE TO RELATED APPLICATIONS

This application is a Continuation of PCT International Application No. PCT/JP2022/034227 filed on Sep. 13, 2022, which claims priority under 35 U.S.C. § 119(a) to Japanese Patent Application No. 2021-152966 filed on Sep. 21, 2021. The above applications are hereby expressly incorporated by reference, in their entirety, into the present application.

### BACKGROUND OF THE INVENTION

### 1. Field of the Invention

The present invention relates to a method for inspecting a treatment liquid and a method for producing a treatment liquid.

### 2. Description of the Related Art

In a process for producing a semiconductor device such as an integrated circuit (IC) or a large scale integrated circuit (LSI), micromachining by a photolithography process using a photoresist composition has been conventionally performed.

In such a photolithography process, after a coating film is formed using a photoresist composition (an actinic ray-sensitive or radiation-sensitive resin composition, also referred to as a chemical amplification resist composition), the coating film obtained is exposed and then developed with a developer to obtain a pattern-shaped cured film, and, furthermore, the cured film after the development is washed with a rinsing liquid.

For example, WO2016/208313A discloses the use of a hydrocarbon solvent as a developer or a rinsing liquid.

### SUMMARY OF THE INVENTION

As described above, WO2016/208313A discloses performing a treatment of a resist film using a developer or rinsing liquid including an aliphatic hydrocarbon solvent. The present inventors have found that the treatment sometimes results in a resist pattern having variation in line width.

An object of the present invention is to provide a method for inspecting a treatment liquid to determine whether the treatment liquid, when used as a developer or a rinsing liquid, allows formation of a resist pattern with reduced variation in line width. Another object of the present invention is to provide a method for producing a treatment liquid.

To achieve the above objects, the present inventors have conducted intensive studies and found that the above objects can be achieved by the following configurations.

[1] A method for inspecting a treatment liquid including an aliphatic hydrocarbon solvent, the method including:
a step A1 of acquiring measurement data of a content of an acid component in the treatment liquid, the acid component being at least one selected from the group consisting of carboxylic acids having a hydrocarbon group having 1 to 3 carbon atoms and formic acid; and
a step A2 of determining whether the measurement data acquired in the step A1 falls within a preset allowable range.

[2] The method for inspecting a treatment liquid according to [1], wherein the aliphatic hydrocarbon solvent includes at least one selected from the group consisting of nonane, decane, undecane, dodecane, and methyldecane.

[3] The method for inspecting a treatment liquid according to [1] or [2], wherein the aliphatic hydrocarbon solvent is undecane.

[4] The method for inspecting a treatment liquid according to any one of [1] to [3], wherein the acid component is acetic acid.

[5] The method for inspecting a treatment liquid according to any one of [1] to [4], wherein the content of the acid component is 1 to 2000 mass ppm relative to a total mass of the treatment liquid.

[6] The method for inspecting a treatment liquid according to any one of [1] to [5], including:
a step B1 of acquiring measurement data of a mass ratio of a content of an ester solvent to a content of the aliphatic hydrocarbon solvent in the treatment liquid; and
a step B2 of determining whether the measurement data acquired in the step B1 falls within a preset allowable range.

[7] The method for inspecting a treatment liquid according to [6], wherein the ester solvent includes at least one selected from the group consisting of butyl acetate, isobutyl acetate, tert-butyl acetate, amyl acetate, isoamyl acetate, propyl propionate, isopropyl propionate, butyl propionate, isobutyl propionate, ethyl butyrate, ethyl isobutyrate, amyl formate, and isoamyl formate.

[8] The method for inspecting a treatment liquid according to [6] or [7], wherein the ester solvent is butyl acetate.

[9] The method for inspecting a treatment liquid according to any one of [1] to [8], including:
a step C1 of acquiring measurement data of a content of an aromatic hydrocarbon in the treatment liquid; and
a step C2 of determining whether the measurement data acquired in the step C1 falls within a preset allowable range.

[10] The method for inspecting a treatment liquid according to [9], wherein the content of the aromatic hydrocarbon is 1 to 2000 mass ppm relative to a total mass of the treatment liquid.

[11] The method for inspecting a treatment liquid according to any one of [1] to [10], including:
a step D1 of acquiring measurement data of a content of an alcohol in the treatment liquid; and
a step D2 of determining whether the measurement data acquired in the step D1 falls within a preset allowable range.

[12] The method for inspecting a treatment liquid according to [11], wherein the content of the alcohol is 1 to 5000 mass ppm relative to a total mass of the treatment liquid.

[13] The method for inspecting a treatment liquid according to any one of [1] to [12], including:
a step E1 of acquiring measurement data of a content of water in the treatment liquid; and
a step E2 of determining whether the measurement data acquired in the step E1 falls within a preset allowable range.

[14] The method for inspecting a treatment liquid according to [13], wherein the content of the water is 1 to 1000 mass ppm relative to a total mass of the treatment liquid.

[15] The method for inspecting a treatment liquid according to any one of [1] to [14], including:
a step F1 of acquiring measurement data of a content of a metallic element in the treatment liquid, the metallic element being at least one selected from the group consisting of Fe, Ni, and Cr; and
a step F2 of determining whether the measurement data acquired in the step F1 falls within a preset allowable range.

[16] The method for inspecting a treatment liquid according to [15], wherein the content of the metallic element is 0.03 to 100 mass ppt relative to a total mass of the treatment liquid.

[17] The method for inspecting a treatment liquid according to any one of [1] to [16], wherein the treatment liquid is a developer or a rinsing liquid.

[18] The method for inspecting a treatment liquid according to any one of [1] to [17], wherein the treatment liquid is used for treatment of a resist composition to be exposed with KrF, ArF, ArF liquid immersion, extreme ultraviolet rays, or an electron beam.

[19] A method for producing a treatment liquid, including the method for inspecting a treatment liquid according to any one of [1] to [18].

The present invention can provide a method for inspecting a treatment liquid to determine whether the treatment liquid, when used as a developer or a rinsing liquid, allows formation of a resist pattern with reduced variation in line width. The present invention can also provide a method for producing a treatment liquid.

### DESCRIPTION OF THE PREFERRED EMBODIMENTS

Hereinafter, the present invention will be described in detail.

It should be appreciated that although the description of constituent features given below may be made on the basis of representative embodiments of the present invention, the present invention is not limited to these embodiments.

In the present specification, any numerical range expressed using “to” means a range including numerical values before and after “to” as lower and upper limit values. In numerical ranges described in stages in the present specification, the upper limit value or the lower limit value described in one numerical range may be replaced with the upper limit value or the lower limit value of other numerical ranges described in stages. In numerical ranges described in the present specification, the upper limit value or the lower limit value described in one numerical range may be replaced with values described in Examples.

In the present specification, if there are two or more substances corresponding to one component in a treatment liquid, the amount of the component in the treatment liquid means the total amount of the two or more substances present in the treatment liquid unless otherwise specified.

In the present invention, “ppm” means “parts-per-million (10⁻⁶)”, “ppb” means “parts-per-billion (10⁻⁹)”, “ppt” means “parts-per-trillion (10⁻¹²)”, and “ppq” means “parts-per-quadrillion (10⁻¹⁵)”.

In the present invention, 1 Å (Angstrom) corresponds to 0.1 nm.

Regarding expressions of groups (atomic groups) in the present invention, an expression not specified as substituted or unsubstituted encompasses a group having no substituents and also a group having a substituent to the extent that the advantageous effects of the present invention are not impaired. For example, a “hydrocarbon group” encompasses not only a hydrocarbon group having no substituents (an unsubstituted hydrocarbon group) but also a hydrocarbon group having a substituent (a substituted hydrocarbon group). This applies to every compound.

The term “actinic ray” or “radiation” in the present specification means, for example, an emission line spectrum of a mercury lamp, far ultraviolet rays represented by excimer lasers, extreme ultraviolet rays (EUV light), X-rays, or an electron beam (EB). The term “light” in the present specification means an actinic ray or a radiation.

The term “exposure” in the present specification includes, unless otherwise specified, not only exposure with, for example, an emission line spectrum of a mercury lamp, far ultraviolet rays represented by excimer lasers, extreme ultraviolet rays, or X-rays but also patterning with a corpuscular beam such as an electron beam or an ion beam.

In the present specification, a combination of two or more preferred embodiments is a more preferred embodiment.

### Method for Inspecting Treatment Liquid

A method for inspecting a treatment liquid according to the present invention (hereinafter also referred to as “the present inspection method”) is a method for inspecting a treatment liquid including an aliphatic hydrocarbon solvent. The method has a step A1 of acquiring measurement data of the content of an acid component (hereinafter also referred to as a “specific acid component”) in the treatment liquid, the acid component being at least one selected from the group consisting of carboxylic acids having a hydrocarbon group having 1 to 3 carbon atoms and formic acid, and a step A2 of determining whether the measurement data acquired in the step A1 falls within a preset allowable range.

By preliminarily determining whether the content of a specific acid component in a treatment liquid falls within an allowable range by the method for inspecting a treatment liquid according to the present invention, whether a resist pattern treated using the treatment liquid has variation in line width can be accurately determined without actually measuring the variation in line width of the resist pattern.

While the reasons therefor have yet to be fully understood, it is presumably because the variation in line width of the resist pattern is closely related to the content of the specific acid component included in the treatment liquid (developer or rinsing liquid) used in forming the resist pattern. While not fully understood, it is presumed that when the specific acid component is present in a predetermined amount, the specific acid component itself can suppress an increase in variation in line width, and, in addition, some interaction with other components that can cause variation in line width occurs to suppress variation in line width.

### Treatment Liquid

Hereinafter, components that are included and can be included in a treatment liquid used in the present inspection method (hereinafter also referred to as “the present treatment liquid”) will be described.

### Aliphatic Hydrocarbon Solvent

The present treatment liquid includes an aliphatic hydrocarbon solvent. The aliphatic hydrocarbon solvent is a component included in the present treatment liquid as an organic solvent.

In the present specification, the organic solvent is an organic solvent contained in an amount of 8000 mass ppm or more relative to the total mass of the present treatment liquid. Organic solvents contained in an amount of less than 8000 mass ppm relative to the total mass of the present treatment liquid fall under the category of organic impurities and are not regarded as the organic solvent.

The aliphatic hydrocarbon solvent may be linear, branched, or cyclic (monocyclic or polycyclic), and is preferably linear. The aliphatic hydrocarbon solvent may be a saturated aliphatic hydrocarbon or an unsaturated aliphatic hydrocarbon.

The number of carbon atoms of the aliphatic hydrocarbon solvent is often 2 or more, preferably 5 or more, more preferably 9 or more. The upper limit is preferably 30 or less, more preferably 20 or less, still more preferably 15 or less, particularly preferably 13 or less. Specifically, the number of carbon atoms of the aliphatic hydrocarbon solvent is preferably 11.

Examples of the aliphatic hydrocarbon solvent include pentane, isopentane, hexane, isohexane, cyclohexane, ethylcyclohexane, methylcyclohexane, heptane, octane, isooctane, nonane, decane, methyldecane, undecane, dodecane, tridecane, tetradecane, pentadecane, hexadecane, heptadecane, 2,2,4-trimethylpentane, and 2,2,3-trimethylhexane.

For higher functions as a developer and a rinsing liquid, the aliphatic hydrocarbon solvent preferably includes an aliphatic hydrocarbon having 5 or more carbon atoms (preferably 20 or less carbon atoms), more preferably includes an aliphatic hydrocarbon having 9 or more carbon atoms (preferably 13 or less carbon atoms), still more preferably includes at least one selected from the group consisting of nonane, decane, undecane, dodecane, and methyldecane, particularly preferably includes undecane, and is most preferably undecane.

One aliphatic hydrocarbon solvent may be used alone, or two or more aliphatic hydrocarbon solvents may be used in combination.

For higher functions as a developer and a rinsing liquid, the content of the aliphatic hydrocarbon solvent is preferably 1 mass % or more and less than 100 mass %, more preferably 2 to 70 mass %, still more preferably 5 to 30 mass %, relative to the total mass of the present treatment liquid.

### Specific Acid Component

The present treatment liquid may include a specific acid component. The specific acid component means carboxylic acids having a hydrocarbon group having 1 to 3 carbon atoms and formic acid, as described above. The specific acid component may be ionized to be present in the form of ions in the present treatment liquid.

The specific acid component may be included in a raw material (e.g., an organic solvent) used to produce the present treatment liquid, may be intentionally added during the process of producing the present treatment liquid, or may be transferred from, for example, an apparatus for producing the present treatment liquid during the process of producing the present treatment liquid (what is called contamination).

Specific examples of carboxylic acids having a hydrocarbon group having 1 to 3 carbon atoms include fatty acids having an alkyl group having 1 to 3 carbon atoms, such as acetic acid, propionic acid, and n-butanoic acid (butyric acid), and polycarboxylic acids having a hydrocarbon group having 1 to 3 carbon atoms, such as malonic acid, succinic acid, glutaric acid, maleic acid, and fumaric acid. Fatty acids having an alkyl group having 1 to 3 carbon atoms are preferred.

Only one specific acid component may be included, or two or more specific acid components may be included.

The content of the specific acid component is not particularly limited, but is preferably 1 to 2000 mass ppm, more preferably 3 to 1200 mass ppm, still more preferably 10 to 30 mass ppm, relative to the total mass of the present treatment liquid.

### Specific Metallic Element

The present treatment liquid may include a metallic element that is at least one selected from the group consisting of Fe, Ni, and Cr (hereinafter also referred to as a “specific metallic element”).

The specific metallic element may be included in the present treatment liquid in the form of particles (metal-containing particles), may be included in the present treatment liquid in the form of ions (metal ions), or may be included in the present treatment liquid in both of these forms.

The specific metallic impurity may be included in a raw material (e.g., an organic solvent) used to produce the present treatment liquid, may be intentionally added during the process of producing the present treatment liquid, or may be transferred from, for example, an apparatus for producing the present treatment liquid during the process of producing the present treatment liquid (what is called contamination).

The content of the specific metallic element is not particularly limited, but is preferably 0.03 to 100 mass ppt, more preferably 3 to 60 mass ppt, still more preferably 3 to 25 mass ppt, relative to the total mass of the present treatment liquid.

Only one specific metallic element may be included, or two or more specific metallic elements may be included. When two or more specific metallic elements are included, their total content is in the above range.

### Ester Solvent

For higher functions as a developer and a rinsing liquid, the present treatment liquid preferably further includes an ester solvent, which is an organic solvent.

The ester solvent may be linear, branched, or cyclic (monocyclic or polycyclic), and is preferably linear.

The number of carbon atoms of the ester solvent is often 2 or more, preferably 3 or more, more preferably 4 or more, still more preferably 6 or more. The upper limit is often 20 or less, preferably 10 or less, more preferably 8 or less, particularly preferably 7 or less. Specifically, the number of carbon atoms of the ester solvent is preferably 6.

Specific examples of the ester solvent include butyl acetate, isobutyl acetate, tert-butyl acetate, methyl acetate, ethyl acetate, propyl acetate, isopropyl acetate, hexyl acetate, methoxybutyl acetate, amyl acetate, isoamyl acetate, methyl formate, ethyl formate, butyl formate, propyl formate, amyl formate, isoamyl formate, methyl lactate, ethyl lactate, butyl lactate, propyl lactate, methyl 2-hydroxyisobutyrate, ethyl butyrate, ethyl isobutyrate, ethyl propionate, propyl propionate, isopropyl propionate, butyl propionate, and isobutyl propionate.

The ester solvent preferably includes at least one selected from the group consisting of butyl acetate, isobutyl acetate, tert-butyl acetate, amyl acetate, isoamyl acetate, propyl propionate, isopropyl propionate, butyl propionate, isobutyl propionate, ethyl butyrate, ethyl isobutyrate, amyl formate, and isoamyl formate, more preferably includes butyl acetate, and is still more preferably butyl acetate.

Only one ester solvent may be included, or two or more ester solvents may be included.

For higher functions as a developer and a rinsing liquid, the content of the ester solvent is preferably 30 to 99 mass %, more preferably 30 to 98 mass %, still more preferably 70 to 95 mass %, relative to the total mass of the present treatment liquid.

### Water

The present treatment liquid may further include water. The water is not particularly limited, and may be, for example, distilled water, ion-exchanged water, or pure water.

The water may be added into the treatment liquid or may be unintentionally incorporated into the present treatment liquid during the process of producing the present treatment liquid. Examples of cases where the water is unintentionally incorporated during the process of producing the present treatment liquid include, but are not limited to, the case where the water is included in a raw material (e.g., an organic solvent) used to produce the present treatment liquid and the case where the water is incorporated during the process of producing the present treatment liquid (e.g., contamination).

The content of the water is not particularly limited, but is preferably 1 to 1000 mass ppm, more preferably 5 to 100 mass ppm, relative to the total mass of the present treatment liquid.

### Aromatic Hydrocarbon

The present treatment liquid may further include an aromatic hydrocarbon. The aromatic hydrocarbon is not included in the above-described organic solvent and falls under the category of organic impurities. In other words, the content of the aromatic hydrocarbon is less than 8000 mass ppm relative to the total mass of the present treatment liquid.

The organic impurities may be added into the present treatment liquid or may be unintentionally incorporated during the process of producing the present treatment liquid. Examples of cases where the organic impurities are unintentionally incorporated during the process of producing the present treatment liquid include, but are not limited to, the case where the organic impurities are contained in a raw material (e.g., an organic solvent) used to produce the present treatment liquid and the case where the organic impurities are incorporated during the process of producing the present treatment liquid (e.g., contamination).

The number of carbon atoms of the aromatic hydrocarbon is preferably 6 to 30, more preferably 6 to 20, still more preferably 10 to 12.

The aromatic ring of the aromatic hydrocarbon may be a monocyclic ring or a polycyclic ring.

The number of ring members of the aromatic ring of the aromatic hydrocarbon is preferably 6 to 12, more preferably 6 to 8, still more preferably 6.

The aromatic ring of the aromatic hydrocarbon may further have a substituent. The substituent is, for example, an alkyl group, an alkenyl group, or a combination thereof. The alkyl group and the alkenyl group may be linear, branched, or cyclic. The number of carbon atoms of the alkyl group and the alkenyl group is preferably 1 to 10, more preferably 1 to 5.

The aromatic ring of the aromatic hydrocarbon is, for example, an optionally substituted benzene ring, an optionally substituted naphthalene ring, or an optionally substituted anthracene ring, preferably an optionally substituted benzene ring.

In other words, the aromatic hydrocarbon is preferably optionally substituted benzene.

The aromatic hydrocarbon preferably includes at least one selected from the group consisting of C₁₀H₁₄, CH₁₁H₁₆, and C₁₀H₁₂.

The aromatic hydrocarbon is also preferably a compound represented by formula (c).

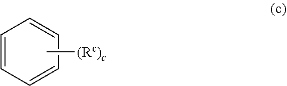

In formula (c), R^{c} represents a substituent, where c represents an integer of 0 to 6.

R^{c} represents a substituent.

The substituent represented by R^{c} is preferably an alkyl group or an alkenyl group.

The alkyl group and the alkenyl group may be linear, branched, or cyclic.

The number of carbon atoms of the alkyl group and the alkenyl group is preferably 1 to 10, more preferably 1 to 5.

When a plurality of R^{c}'s are present, the plurality of R^{c}'s may be the same or different, and the plurality of R^{c}'s may be bonded to each other to form a ring.

R^{c} (when a plurality of R^{c}'s are present, some or all of the plurality of R^{c}'s) and the benzene ring in formula (c) may be fused to form a fused ring.

c represents an integer of 0 to 6.

c is preferably an integer of 1 to 5, more preferably an integer of 1 to 4.

The molecular weight of the aromatic hydrocarbon is preferably 50 or more, more preferably 100 or more, still more preferably 120 or more. The upper limit is preferably 1000 or less, more preferably 300 or less, still more preferably 150 or less.

Examples of the aromatic hydrocarbon include C₁₀H₁₄ such as 1,2,4,5-tetramethyl-benzene, 1-ethyl-3,5-dimethyl-benzene, 1,2,3,5-tetramethyl-benzene, and 1-ethyl-2,4-dimethyl-benzene; C₁₁H₁₆ such as 1-methyl-4-(1-methylpropyl)-benzene and (1-methybutyl)-benzene; and C₁₀H₁₂ such as 1-methyl-2-(2-propenyl)-benzene and 1,2,3,4-tetrahydro-naphthalene.

The aromatic hydrocarbon is preferably 1,2,4,5-tetramethyl-benzene, 1-ethyl-3,5-dimethyl-benzene, 1,2,3,5-tetramethyl-benzene, 1-methyl-4-(1-methylpropyl)-benzene, or C₁₀H₁₂, more preferably 1-ethyl-3,5-dimethyl-benzene or 1,2,3,5-tetramethyl-benzene.

Only one aromatic hydrocarbon may be included, or two or more aromatic hydrocarbons may be included.

The content of the aromatic hydrocarbon is not particularly limited, but is preferably 1 to 2000 mass ppm, more preferably 10 to 1200 mass ppm, still more preferably 60 to 360 mass ppm, relative to the total mass of the present treatment liquid.

### Alcohol

The present treatment liquid may further include an alcohol, which is an organic impurity. The alcohol is not included in the above-described organic solvent and falls under the category of organic impurities. In other words, the content of the alcohol is less than 8000 mass ppm relative to the total mass of the treatment liquid.

The number of carbon atoms of the alcohol is preferably 1 to 20, more preferably 1 to 5, still more preferably 2 to 5.

The alcohol preferably includes at least one selected from the group consisting of ethanol, 1-propanol, 2-propanol, 1-butanol, 2-butanol, tert-butanol, 1-pentanol, 2-pentanol, 3-pentanol, and 2-methyl-1-butanol, more preferably includes 1-butanol, 2-butanol, or tert-butanol, still more preferably includes 1-butanol.

Only one alcohol may be included, or two or more alcohols may be included.

The content of the alcohol is not particularly limited, but is preferably 1 to 5000 mass ppm, more preferably 10 to 400 mass ppm, still more preferably 20 to 60 mass ppm, relative to the total mass of the present treatment liquid.

### Other Components

The present treatment liquid may include other components other than the foregoing.

Examples of the other components include organic solvents such as ketone solvents, amide solvents, and ether solvents, surfactants, and sulfur-containing components.

### Applications

Preferably, the present treatment liquid is suitably used as a developer or a rinsing liquid for use in the process of manufacturing a semiconductor device.

The present treatment liquid is also preferably used for treatment (particularly, development) of a resist composition (particularly, a negative-type resist film) to be exposed with KrF, ArF, ArF liquid immersion, extreme ultraviolet rays (EUV), or an electron beam (EB).

The present treatment liquid can also be used as a prewetting liquid for use in the process of manufacturing a semiconductor device.

The present treatment liquid can also be used as a washing liquid for an end face and a peripheral inclined portion (bevel) of a wafer or a back-surface washing liquid (a washing liquid for a surface of a wafer on the side opposite to the side on which a semiconductor substrate is formed).

The present treatment liquid can also be used as a washing liquid for various manufacturing facilities, coating treatment apparatuses, and transfer containers.

### Step A1 and Step A2

The present inspection method has a step A1 of acquiring measurement data of the content of a specific acid component in the present treatment liquid and a step A2 of determining whether the measurement data acquired in the step A1 falls within a preset allowable range.

In the step A1, the type identification and content measurement of the specific acid component in the present treatment liquid can be performed using gas chromatography mass spectrometry (GCMS).

The allowable range in the step A2 is preset before the step A1 is performed. Using this allowable range, when the measurement data acquired in the step A1 falls within the allowable range, it is determined as “acceptable”, and when the measurement data does not fall within the allowable range, it is determined as “unacceptable”.

A treatment liquid determined as acceptable by the present inspection method allows formation of a resist pattern with reduced variation in line width.

The allowable range used in the step A2 can be set, for example, as follows.

First, a plurality of treatment liquids containing the specific acid component in known amounts different from each other are provided, and each treatment liquid is used to perform treatment (development or rinsing) of a resist film to obtain a resist pattern.

Next, the variation in line width of each resist pattern obtained is measured, and a treatment liquid used to form a resist pattern whose variation in line width is within allowable limits is selected. On the basis of the content of the specific acid component in the treatment liquid selected, the range of the content of the specific acid component in the treatment liquid is set as the allowable range.

The content of the specific acid component that can be set as the allowable range is preferably 2000 mass ppm or less, more preferably 1200 mass ppm or less, still more preferably 30 mass ppm or less, relative to the total mass of the present treatment liquid.

The step A2 of determining whether the measurement data falls within the allowable range is performed with, for example, a processing apparatus configured using hardware such as a computer. An exemplary configuration of a processing apparatus that performs the determination in the step A2 will be described below, but the step A2 is not necessarily performed with the following processing apparatus.

The processing apparatus has an input unit, a processing unit, a storage unit, and an output unit. Memory has memory that can store external data and read-only memory (ROM).

The processing apparatus may be configured with a computer in which each part functions upon execution of a program stored in ROM or may be a dedicated apparatus in which each part is configured with a dedicated circuit. The program is provided in the form of, for example, computer software.

The input unit is a part having a function to input the measurement data acquired in the step A1, and may be, for example, an input device such as a mouse or a keyboard or may be a measuring device that executes the step A1.

The processing unit is a part that performs the determination in the step A2. More specifically, the processing unit receives the measurement data acquired in the step A1 from the input unit and also reads the allowable range stored in the storage unit, and compares the measurement data with the allowable range to determine whether the measurement data falls within the allowable range. The processing unit, in accordance with a preset program, performs a predetermined control on the output unit according to the determination result. The processing unit stores the measurement data input from the input unit in the storage unit. In some cases, the processing unit, on the basis of data selected from the group consisting of the measurement data input from the input unit and past measurement data stored in the storage unit, calculates new reference data and a new allowable range and stores them in the storage unit.

The output unit is a part having a function to output the determination result in the step A2; examples include a display device such as a display configured to display the determination result, a device such as a printer configured to present the determination result on an output medium, a sound output device configured to output an alarm, and communication means configured to notify the user of the determination result.

In the step A2, when the measurement data acquired in the step A1 does not fall within the allowable range (when the determination result is unacceptable), the processing unit may control the output unit to perform an action selected from the group consisting of showing that the determination result is unacceptable (e.g., display on the display device or presentation on the output medium) and giving the user a warning (e.g., an alarm or a notification). This can notify the user that the measurement data acquired in the step A1 does not fall within the allowable range and prompt the user to actions such as suspension of the production of the treatment liquid and disposal or purification of the treatment liquid of the same lot as the treatment liquid whose measurement data has been acquired.

When the measurement data acquired in the step A1 falls within the allowable range (when the determination result is acceptable), the processing unit may control the output unit to perform an action selected from the group consisting of showing that the determination result is acceptable (e.g., display on the display device or presentation on the output medium) and giving the user a notification.

The processing apparatus may have a production unit (production device) configured to produce the treatment liquid, and the processing unit may be connected to the production unit through an electric circuit. For example, when the measurement data acquired in the step A1 is determined not to fall within the allowable range in the step A2 (when the determination result is unacceptable), the processing unit may control the production unit to stop the production of the treatment liquid. When the measurement data acquired in the step A1 falls within the allowable range (when the determination result is acceptable), the processing unit may control the production unit to continue the production of the treatment liquid.

The production unit may have any configuration as long as it can produce the treatment liquid, and a known production device can be appropriately used.

### Other Steps

The present inspection method may further have other steps other than the step A1 and the step A2. Examples of the other steps include a step B1 and a step B2, a step C1 and a step C2, a step D1 and a step D2, a step E1 and a step E2, and a step F1 and a step F2.

### Step B1 and Step B2

The present inspection method may have a step B1 of acquiring measurement data of the mass ratio of the content of an ester solvent to the content of an aliphatic hydrocarbon solvent in the present treatment liquid and a step B2 of determining whether the measurement data acquired in the step B1 falls within a preset allowable range.

With these steps, whether the treatment liquid is excellent in sensitivity (the ratio relative to set sensitivity) can be accurately determined without actually treating a resist film with the present treatment liquid.

In the step B1, the type identification, content measurement, and mass ratio measurement of the aliphatic hydrocarbon solvent and the ester solvent in the present treatment liquid can be performed using gas chromatography mass spectrometry (GCMS).

The allowable range in the step B2 is preset before the step B1 is performed. Using this allowable range, when the measurement data acquired in the step B1 falls within the allowable range, it is determined as “acceptable”, and when the measurement data does not fall within the allowable range, it is determined as “unacceptable”.

A treatment liquid determined as acceptable by the present inspection method can be said to be excellent in the ratio relative to set sensitivity.

The allowable range used in the step B2 can be set, for example, as follows.

First, a plurality of treatment liquids containing the aliphatic hydrocarbon solvent and the ester solvent in known mass ratios different from each other are provided, and each treatment liquid is used to perform treatment (development or rinsing) of a resist film to obtain a resist pattern.

Next, the sensitivity of each resist pattern obtained is measured, and a treatment liquid used to form a resist pattern whose ratio relative to set sensitivity is within allowable limits is selected. On the basis of the mass ratio in the treatment liquid selected, the range of the mass ratio in the treatment liquid is set as the allowable range.

The mass ratio that can be set as the allowable range is preferably 0.4 to 99.0, more preferably 2.3 to 49.0, still more preferably 2.3 to 19.0, particularly preferably 8.1 to 10.1.

The processing apparatus used in the step B2 is the same as the processing apparatus described in the step A2 and thus will not be elaborated here.

### Step C1 and Step C2

The present inspection method may have a step C1 of acquiring measurement data of the content of an aromatic hydrocarbon in the present treatment liquid and a step C2 of determining whether the measurement data acquired in the step C1 falls within a preset allowable range.

With these steps, whether a resist pattern with few bridge defects can be formed can be accurately determined without actually treating a resist film with the present treatment liquid. Here, a bridge defect means a bridge-like defect where portions of a resist pattern formed are connected to each other.

In the step C1, the type identification and content measurement of the aromatic hydrocarbon in the present treatment liquid can be performed using gas chromatography mass spectrometry (GCMS).

The allowable range in the step C2 is preset before the step C1 is performed. Using this allowable range, when the measurement data acquired in the step C1 falls within the allowable range, it is determined as “acceptable”, and when the measurement data does not fall within the allowable range, it is determined as “unacceptable”.

A treatment liquid determined as acceptable by the present inspection method allows formation of a resist pattern with few bridge defects.

The allowable range used in the step C2 can be set, for example, as follows.

First, a plurality of treatment liquids containing the aromatic hydrocarbon in known amounts different from each other are provided, and each treatment liquid is used to perform treatment (development or rinsing) of a resist film to obtain a resist pattern.

Next, the bridge defect of each resist pattern obtained is measured, and a treatment liquid used to form a resist pattern whose bridge defect is within allowable limits is selected. On the basis of the content of the aromatic hydrocarbon in the treatment liquid selected, the range of the content of the aromatic hydrocarbon in the treatment liquid is set as the allowable range.

The content of the aromatic hydrocarbon that can be set as the allowable range is preferably 2000 mass ppm or less relative to the total mass of the present treatment liquid.

The processing apparatus used in the step C2 is the same as the processing apparatus described in the step A2 and thus will not be elaborated here.

### Step D1 and Step D2

The present inspection method may have a step D1 of acquiring measurement data of the content of an alcohol in the present treatment liquid and a step D2 of determining whether the measurement data acquired in the step D1 falls within a preset allowable range.

With these steps, whether a resist pattern with few defects can be obtained can be accurately determined without actually treating a resist film with the present treatment liquid.

In the step D1, the type identification and content measurement of the alcohol in the present treatment liquid can be performed using gas chromatography mass spectrometry (GCMS).

The allowable range in the step D2 is preset before the step D1 is performed. Using this allowable range, when the measurement data acquired in the step D1 falls within the allowable range, it is determined as “acceptable”, and when the measurement data does not fall within the allowable range, it is determined as “unacceptable”.

A treatment liquid determined as acceptable by the present inspection method allows formation of a resist pattern with few defects.

The allowable range used in the step D2 can be set, for example, as follows.

First, a plurality of treatment liquids containing the alcohol in known amounts different from each other are provided, and each treatment liquid is used to perform treatment (development or rinsing) of a resist film to obtain a resist pattern.

Next, the number of defects of each resist pattern obtained is measured, and a treatment liquid used to form a resist pattern whose number of defects is within allowable limits is selected. On the basis of the content of the alcohol in the treatment liquid selected, the range of the content of the alcohol in the treatment liquid is set as the allowable range.

The content of the alcohol that can be set as the allowable range is preferably 5000 mass ppm or less, more preferably 150 mass ppm or less, still more preferably 60 mass ppm or less, relative to the total mass of the present treatment liquid.

The processing apparatus used in the step D2 is the same as the processing apparatus described in the step A2 and thus will not be elaborated here.

### Step E1 and Step E2

The present inspection method may have a step E1 of acquiring measurement data of the content of water in the present treatment liquid and a step E2 of determining whether the measurement data acquired in the step E1 falls within a preset allowable range.

With these steps, whether a resist pattern resistant to pattern collapse can be formed can be accurately determined without actually treating a resist film with the present treatment liquid.

In the step E1, the content of water in the present treatment liquid can be measured using an apparatus whose measurement principle is based on Karl Fischer water titration.

The allowable range in the step E2 is preset before the step E1 is performed. Using this allowable range, when the measurement data acquired in the step E1 falls within the allowable range, it is determined as “acceptable”, and when the measurement data does not fall within the allowable range, it is determined as “unacceptable”.

A treatment liquid determined as acceptable by the present inspection method allows formation of a resist pattern resistant to pattern collapse.

The allowable range used in the step E2 can be set, for example, as follows.

First, a plurality of treatment liquids containing water in known amounts different from each other are provided, and each treatment liquid is used to perform treatment (development or rinsing) of a resist film to obtain a resist pattern.

Next, the pattern collapse of each resist pattern obtained is measured, and a treatment liquid used to form a resist pattern whose pattern collapse is within allowable limits is selected. On the basis of the content of water in the treatment liquid selected, the range of the content of water in the treatment liquid is set as the allowable range.

The content of water that can be set as the allowable range is preferably 1000 mass ppm or less, more preferably 100 mass ppm or less, relative to the total mass of the present treatment liquid.

The processing apparatus used in the step E2 is the same as the processing apparatus described in the step A2 and thus will not be elaborated here.

### Step F1 and Step F2

The present inspection method may have a step F1 of acquiring measurement data of the content of a specific metallic element in the present treatment liquid and a step F2 of determining whether the measurement data acquired in the step F1 falls within a preset allowable range.

With these steps, whether a resist pattern with few defects including a metallic element (metal-containing defects) can be formed can be accurately determined without actually treating a resist film with the present treatment liquid.

The measurement of the type and content of the specific metallic element can be performed using an apparatus whose measurement principle is based on inductively coupled plasma mass spectrometry (ICP-MS).

In ICP-MS, the content of a metallic element to be measured is measured regardless of the form in which it is present.

For example, when the specific metallic impurity is included in the present treatment liquid in the form of metal-containing particles, the content of the specific metallic element in the metal-containing particles is measured. When the specific metallic impurity is included in the present treatment liquid in the form of metal ions, the content of the specific metallic element corresponding to the metal ions is measured. When the specific metallic impurity is included in the present treatment liquid in the forms of both metal-containing particles and metal ions, the sum of the content of the specific metallic element in the metal-containing particles and the content of the specific metallic element corresponding to the metal ions is measured.

The apparatus for ICP-MS is, for example, Agilent 8900 Triple Quadrupole ICP-MS (inductively coupled plasma mass spectrometry, for semiconductor analysis, option #200) manufactured by Agilent Technologies, Inc., and the measurement can be performed by a method described in EXAMPLES. As an alternative to this apparatus, NexION350S manufactured by PerkinElmer, Inc. or Agilent 8800 manufactured by Agilent Technologies, Inc. can also be used.

The allowable range in the step F2 is preset before the step F1 is performed. Using this allowable range, when the measurement data acquired in the step F1 falls within the allowable range, it is determined as “acceptable”, and when the measurement data does not fall within the allowable range, it is determined as “unacceptable”.

A treatment liquid determined as acceptable by the present inspection method allows formation of a resist pattern with few metal-containing defects.

The allowable range used in the step F2 can be set, for example, as follows.

First, a plurality of treatment liquids containing the specific metallic element in known amounts different from each other are provided, and each treatment liquid is used to perform treatment (development or rinsing) of a resist film to obtain a resist pattern.

Next, the number of metal-containing defects of each resist pattern obtained is measured, and a treatment liquid used to form a resist pattern whose number of metal-containing defects is within allowable limits is selected. On the basis of the content of the specific metallic element in the treatment liquid selected, the range of the content of the specific metallic element in the treatment liquid is set as the allowable range.

The content of the specific metallic element that can be set as the allowable range is preferably 100 mass ppt or less, more preferably 60 mass ppt or less, still more preferably 30 mass ppt or less, relative to the total mass of the present treatment liquid.

The processing apparatus used in the step F2 is the same as the processing apparatus described in the step A2 and thus will not be elaborated here.

### Method for Producing Treatment Liquid

The present treatment liquid may be produced by any method. The method may have, in addition to the above-described steps, a filtration step of filtering a purification target substance including an organic solvent using a filter.

The purification target substance used in the filtration step may be procured by purchase or the like or may be obtained by reacting raw materials together. The purification target substance preferably has a low impurity content. Examples of commercially available products of such a purification target substance include commercially available products called “high purity grade products”.

The method of obtaining a purification target substance (typically, a purification target substance containing an organic solvent) by reacting raw materials together is not particularly limited, and a known method can be used. For example, an organic solvent may be obtained by reacting one or more raw materials together in the presence of a catalyst.

### Filtration Step

A method for producing the present treatment liquid according to an embodiment of the present invention has a filtration step of filtering the purification target substance using a filter to obtain the present treatment liquid. The method of filtering the purification target substance using a filter is not particularly limited, but the purification target substance is preferably allowed to pass (flow) through a filter unit having a housing and a filter cartridge housed in the housing under pressure or non-pressure conditions.

### Pore Size of Filter

The pore size of the filter is not particularly limited, and a filter having a pore size commonly used for purification target substance filtration can be used. In particular, to more easily control the number of particles (e.g., metal-containing particles) that can be included in the present treatment liquid within a desired range, the pore size of the filter is preferably 200 nm or less, more preferably 20 nm or less, still more preferably 10 nm or less, particularly preferably 5 nm or less, most preferably 3 nm or less. The lower limit is not particularly limited, but in general, the lower limit is preferably 1 nm or more from the viewpoint of productivity.

In the present specification, the pore size and the pore size distribution of the filter mean a pore size and a pore size distribution determined using the bubble point of isopropanol (IPA) or HFE-7200 (“Novec 7200” manufactured by 3M, hydrofluoroether, C₄F₉OC₂H₅).

When the pore size of the filter is 5.0 nm or less, it is advantageous in that the number of particles contained in the present treatment liquid is more easily controlled. Hereinafter, a filter having a pore size of 5 nm or less is also referred to as a “micropore filter”.

The micropore filter may be used alone or in combination with a filter having a different pore size. In particular, combined use with a filter having a larger pore size is preferred from the viewpoint of higher productivity. If, in this case, the purification target substance preliminarily filtered through the filter having a larger pore size is allowed to flow through the micropore filter, clogging of the micropore filter can be prevented.

That is, when one filter is used, the pore size of the filter is preferably 5.0 nm or less, and when two or more filters are used, the pore size of a filter having a smallest pore size is preferably 5.0 nm or less.

The configuration in which two or more filters having different pore sizes are sequentially used is not particularly limited, but, for example, filter units as already described may be sequentially disposed along a conduit through which the purification target substance is transported. At this time, if the flow rate per unit time of the purification target substance is constant through the whole conduit, a filter unit having a smaller pore size may be subjected to a higher pressure than a filter unit having a larger pore size. In this case, it is preferable to make the pressure on the filter unit having a smaller pore size constant by disposing a pressure-regulating valve, a damper, and the like between the filter units or to increase the filtration area by disposing filter units housing the same filter in parallel along the conduit. This enables the number of particles in the present treatment liquid to be more stably controlled.

### Material of Filter

The material of the filter is not particularly limited and may be a known material. Specifically, in the case of a resin, examples include polyamides such as nylon (e.g., 6-nylon and 6,6-nylon); polyolefins such as polyethylene and polypropylene; polystyrene; polyimide; polyamide-imide; poly(meth)acrylate; polyfluorocarbons such as polytetrafluoroethylene, perfluoroalkoxyalkanes, perfluoroethylene propene copolymer, ethylene tetrafluoroethylene copolymer, ethylene-chlorotrifluoroethylene copolymer, polychlorotrifluoroethylene, polyvinylidene fluoride, and polyvinyl fluoride; polyvinyl alcohol; polyester; cellulose; and cellulose acetate. In particular, in terms of having higher solvent resistance and providing the present treatment liquid with higher defect suppression performance, at least one selected from the group consisting of nylon (particularly, 6,6-nylon is preferred), polyolefins (particularly, polyethylene is preferred), poly(meth)acrylate, and polyfluorocarbons (particularly, polytetrafluoroethylene (PTFE) and perfluoroalkoxyalkanes (PFA) are preferred) is preferred. These polymers can be used alone or in combination of two or more.

In addition to the resins, diatomaceous earth, glass, and the like may be used.

Alternatively, a polymer (e.g., nylon-grafted UPE) obtained by graft copolymerization of a polyolefin (e.g., UPE described later) with a polyamide (e.g., nylon such as nylon-6 or nylon-6,6) may be used as the material of the filter.

The filter may be a surface-treated filter. The method of the surface treatment is not particularly limited, and a known method can be used. Examples of the method of the surface treatment include chemical modification treatment, plasma treatment, hydrophilic/hydrophobic treatment, coating, gas treatment, and sintering.

The plasma treatment is preferred because the surface of the filter is hydrophilized. The water contact angle on the surface of the filtering material hydrophilized as a result of the plasma treatment is not particularly limited, but the static contact angle at 25° C. as measured with a contact angle meter is preferably 60° or less, more preferably 500 or less, particularly preferably 30° or less.

The chemical modification treatment is preferably introduction of an ion-exchange group into a base material.

That is, the filter is preferably a filter including any of the materials listed above as a base material and an ion-exchange group introduced into the base material. Typically, a filter including a layer including the base material containing, on its surface, an ion-exchange group is preferred. The surface-modified base material is not particularly limited, and in terms of easier production, a filter obtained by introducing an ion-exchange group into any of the foregoing polymers is preferred.

Examples of the ion-exchange group include cation-exchange groups such as a sulfonate group, a carboxy group, and a phosphate group and anion-exchange groups such as a quaternary ammonium group. Examples of methods of introducing an ion-exchange group into the polymer include, but are not limited to, reacting a compound containing an ion-exchange group and a polymerizable group with a polymer to cause, typically, grafting.

The ion-exchange group may be introduced by any method. For example, a fiber of any of the foregoing resins is irradiated with ionizing radiation (e.g., α-rays, β-rays, γ-rays, X-rays, or electron beams) to produce active moieties (radicals) in the resin. The resin that has been subjected to the irradiation is immersed in a monomer-containing solution to graft-polymerize the monomer onto the base material. As a result of this, a polymer in which the monomer is bonded to the polyolefin fiber as a graft-polymerized side chain is produced. The resin containing the produced polymer as a side chain is allowed to undergo a catalytic reaction with a compound containing an anion-exchange group or a cation-exchange group to introduce the ion-exchange group into the graft-polymerized side-chain polymer, thus providing a final product.

The filter may be in the form of a combination of a woven or nonwoven fabric on which an ion-exchange group is formed by radiation-induced graft polymerization and a conventional filtering material made of glass wool or a woven or nonwoven fabric.

When a filter containing an ion-exchange group is used, the content of particles containing a metal atom in the present treatment liquid is more easily controlled within a desired range. The material of the filter containing an ion-exchange group is not particularly limited, but is, for example, a material obtained by introducing the ion-exchange group into a polyfluorocarbon or a polyolefin, more preferably a material obtained by introducing the ion-exchange group into a polyfluorocarbon.

The pore size of the filter containing an ion-exchange group is not particularly limited, but is preferably 1 to 200 nm, more preferably 1 to 30 nm, still more preferably 3 to 20 nm. The filter containing an ion-exchange group may also serve as the filter having a smallest pore size already described or may be used separately from the filter having a smallest pore size. In particular, to provide the present treatment liquid that produces the advantageous effects of the present invention in a better manner, the filter containing an ion-exchange group and the filter not having an ion-exchange group and having a smallest pore size are preferably used in the filtration step.

The material of the filter having a smallest pore size already described is not particularly limited, but from the viewpoint of, for example, solvent resistance, in general, the material is preferably at least one selected from the group consisting of polyfluorocarbons and polyolefins, more preferably a polyolefin.

Thus, as the filter used in the filtration step, two or more filters made of different materials may be used, and, for example, two or more selected from the group consisting of filters made of polyolefins, polyfluorocarbons, polyamides, and materials obtained by introducing an ion-exchange group into these materials may be used.

### Pore Structure of Filter

The pore structure of the filter is not particularly limited and may be appropriately selected depending on the components in the purification target substance. In the present specification, the pore structure of the filter means pore size distribution, positional distribution of pores in the filter, pore shape, etc. and can be controlled typically by how the filter is produced.

For example, formation by sintering of powder of a resin or the like provides a porous membrane, and formation by a method such as electrospinning, electroblowing, or melt blowing provides a fibrous membrane. These membranes have different pore structures.

The term “porous membrane” refers to a membrane that retains components such as gels, particles, colloids, cells, and polyoligomers in the purification target substance but allows components that are substantially smaller than pores to pass through the pores. The retention of the components in the purification target substance by the porous membrane may depend on operating conditions such as face velocity, use of a surfactant, pH, and combinations thereof, and can depend on the pore size and structure of the porous membrane and the size and structure (e.g., hard or gelatinous) of particles to be removed.

When the purification target substance contains negatively charged particles, a polyamide filter functions as a non-sieving membrane to remove such particles. Typical non-sieving membranes include nylon membranes such as nylon-6 membranes and nylon-6,6 membranes, but are not limited thereto.

As used herein, the term “non-sieving” retention mechanism refers to retention caused by mechanisms such as blocking, diffusion, and adsorption not associated with the pressure drop or pore size of the filter.

Non-sieving retention includes retention mechanisms such as blocking, diffusion, and adsorption by which particles to be removed in the purification target substance are removed independent of the pressure drop of the filter or the pore size of the filter. The adsorption of particles to the filter surface can be mediated by, for example, the intermolecular van der Waals force and electrostatic force. The blocking effect occurs when particles moving through a non-sieving membrane layer having a meandering path cannot turn sufficiently fast so as to avoid contact with the non-sieving membrane. Particle transport by diffusion results mainly from the random or Brownian motion of small particles, which creates a certain probability of the particles colliding with the filtering material. When there is no repulsive force between the particles and the filter, the non-sieving retention mechanism can be active.

An ultra-high molecular weight polyethylene (UPE) filter is typically a sieving membrane. The sieving membrane means a membrane that captures particles mainly through the sieving retention mechanism or a membrane optimized in order to capture particles through the sieving retention mechanism.

Typical examples of the sieving membrane include polytetrafluoroethylene (PTFE) membranes and UPE membranes, but are not limited thereto.

The term “sieving retention mechanism” refers to retention resulting from the size of particles to be removed larger than the pore size of the porous membrane. The sieving retention force can be improved by formation of a filter cake (aggregation of particles to be removed on the surface of the membrane). The filter cake effectively functions as a secondary filter.

The material of the fibrous membrane is not particularly limited as long as it is a polymer that can form into the fibrous membrane. Examples of the polymer include polyamides. Examples of polyamides include nylon 6 and nylon 6,6. The polymer forming the fibrous membrane may be poly(ether sulfone). When the fibrous membrane is on the upstream side of the porous membrane, the surface energy of the fibrous membrane is preferably higher than that of a polymer forming the porous membrane on the downstream side. An example of such a combination is the case where the fibrous membrane is made of nylon and the porous membrane is made of polyethylene (UPE).

The method of producing the fibrous membrane is not particularly limited, and a known method can be used. Examples of the method of producing the fibrous membrane include electrospinning, electroblowing, and melt blowing.

The pore structure of the porous membrane (e.g., a porous membrane including UPE, PTFE, or the like) is not particularly limited, and the shape of pores may be, for example, a lace shape, a string shape, or a node shape.

The size distribution of pores in the porous membrane and their positional distribution in the membrane are not particularly limited. The size distribution may be narrower, and the positional distribution in the membrane may be symmetric. Alternatively, the size distribution may be wider, and the positional distribution in the membrane may be asymmetric (such a membrane is also referred to as an “asymmetric porous membrane”). In the case of an asymmetric porous membrane, the pore size varies in the membrane; typically, the pore size increases from one surface of the membrane toward the other surface of the membrane. Here, a surface on the side on which pores having larger sizes are predominant is also referred to as the “open side”, and a surface on the side on which pores having smaller sizes are predominant is also referred to as the “tight side”.

The asymmetric porous membrane may be, for example, a membrane in which the pore size minimizes at a certain position in the thickness direction of the membrane (this is also referred to as an “hourglass shape”).

Using the asymmetric porous membrane such that pores having larger sizes are present on the upstream side, that is, the upstream side is the open side, can produce a prefiltering effect.

The porous membrane may include a thermoplastic polymer such as polyethersulfone (PESU), a perfluoroalkoxyalkane (PFA, tetrafluoroethylene/perfluoroalkoxyalkane copolymer), a polyamide, or a polyolefin, or may include polytetrafluoroethylene or the like.

In particular, the material of the porous membrane is preferably ultra-high molecular weight polyethylene. The ultra-high molecular weight polyethylene, which means a thermoplastic polyethylene having an extremely long chain, has a molecular weight of 1,000,000 or more, typically preferably 2,000,000 to 6,000,000.

As the filter used in the filtration step, two or more filters having different pore structures may be used, or a porous membrane filter and a fibrous membrane filter may be used in combination. Specifically, for example, a nylon fibrous membrane filter and a UPE porous membrane filter may be used.

Preferably, the filter is sufficiently washed before use.

When an unwashed filter (or an insufficiently washed filter) is used, impurities contained in the filter tend to be incorporated into the present treatment liquid.

Examples of the impurities contained in the filter include the organic impurities described above, and if the filtration step is performed using an unwashed filter (or an insufficiently washed filter), the content of the organic impurities in the present treatment liquid may exceed the allowable range for the present treatment liquid.

For example, when a polyolefin such as UPE or a polyfluorocarbon such as PTFE is used for the filter, the filter tends to contain, as an impurity, an alkane having 12 to 50 carbon atoms. When a polyamide such as nylon, a polyimide, or a polymer obtained by graft copolymerization of a polyolefin (e.g., UPE) with a polyamide (e.g., nylon) is used for the filter, the filter tends to contain, as an impurity, an alkene having 12 to 50 carbon atoms.

The method of washing the filter is, for example, immersion of the filter in an organic solvent having a low impurity content (e.g., an organic solvent purified by distillation (e.g., PGMEA)) for one week or more. In this case, the temperature of the organic solvent is preferably 30° C. to 90° C.

The degree of washing of the filter may be adjusted so that filtering the purification target substance using the filter provides a treatment liquid containing a desired amount of filter-derived organic impurities.

The filtration step may be a multistage filtration step in which the purification target substance is passed through two or more filters different in at least one selected from the group consisting of filter material, pore size, and pore structure.

The purification target substance may be passed through the same filter for multiple times, or the purification target substance may be passed through multiple filters of the same type.

The path of filtration is not particularly limited. Single-pass filtration may be employed, or cycle filtration may be performed with a circulation path assembled.

The material of a liquid-contact portion (which means an inner wall surface and other portions with which the purification target substance and the treatment liquid can come into contact) of a purification apparatus used in the filtration step is not particularly limited, but the liquid-contact portion is preferably formed of at least one selected from the group consisting of nonmetal materials (e.g., fluorocarbon resins) and electropolished metal materials (e.g., stainless steel) (hereinafter, these are also referred to collectively as “corrosion-resistant materials”). For example, when the liquid-contact portion of a production tank is formed of a corrosion-resistant material, the production tank itself may be formed of the corrosion-resistant material, or the inner wall surface and other portions of the production tank may be coated with the corrosion-resistant material.

The nonmetal material is not particularly limited, and a known material can be used.

Examples of the nonmetal material include at least one selected from the group consisting of polyethylene resin, polypropylene resin, polyethylene-polypropylene resin, and fluorocarbon resins (e.g., tetrafluoroethylene resin, tetrafluoroethylene-perfluoroalkyl vinyl ether copolymer, tetrafluoroethylene-hexafluoropropylene copolymer resin, tetrafluoroethylene-ethylene copolymer resin, trifluorochloroethylene-ethylene copolymer resin, vinylidene fluoride resin, trifluorochloroethylene copolymer resin, and vinyl fluoride resin), but are not limited thereto.

The metal material is not particularly limited, and a known material can be used.

The metal material is, for example, a metal material in which the total content of chromium and nickel is more than 25 mass % relative to the total mass of the metal material. In particular, the total content of chromium and nickel is more preferably 30 mass % or more. The upper limit of the total content of chromium and nickel in the metal material is not particularly limited, but in general, the upper limit is preferably 90 mass % or less.

The metal material is, for example, stainless steel or a nickel-chromium alloy.

The stainless steel is not particularly limited, and a known stainless steel can be used. In particular, an alloy containing 8 mass % or more of nickel is preferred, and an austenitic stainless steel containing 8 mass % or more of nickel is more preferred. Examples of the austenitic stainless steel include steel use stainless (SUS) 304 (Ni content, 8 mass %; Cr content, 18 mass %), SUS304L (Ni content, 9 mass %; Cr content, 18 mass %), SUS316 (Ni content, 10 mass %; Cr content, 16 mass %), and SUS316L (Ni content, 12 mass %; Cr content, 16 mass %).

The nickel-chromium alloy is not particularly limited, and a known nickel-chromium alloy can be used. In particular, a nickel-chromium alloy having a nickel content of 40 to 75 mass % and a chromium content of 1 to 30 mass % is preferred.

Examples of the nickel-chromium alloy include Hastelloy (product name, hereinafter the same), Monel (product name, hereinafter the same), and Inconel (product name, hereinafter the same). More specific examples include Hastelloy C-276 (Ni content, 63 mass %; Cr content, 16 mass %), Hastelloy-C(Ni content, 60 mass %; Cr content, 17 mass %), and Hastelloy C-22 (Ni content, 61 mass %; Cr content, 22 mass %).

If necessary, the nickel-chromium alloy may further contain, in addition to the above alloys, boron, silicon, tungsten, molybdenum, copper, cobalt, and the like.

The method of electropolishing the metal material is not particularly limited, and a known method can be used. For example, methods described in, for example, paragraphs [0011] to [0014] of JP2015-227501A and paragraphs [0036] to [0042] of JP2008-264929A can be used.

It is presumed that in the metal material, the chromium content in a surface passivation layer has been increased by electropolishing to be higher than the chromium content in the matrix. Thus, it is presumed that when a purification apparatus whose liquid-contact portion is formed of an electropolished metal material is used, metal-containing particles are less likely to flow out into the purification target substance.

The metal material may be buffed. The method of buffing is not particularly limited, and a known method can be used. The size of polishing abrasive grains used for the finish of buffing is not particularly limited, but is preferably #400 or less to readily reduce surface irregularities of the metal material. The buffing is preferably performed before the electropolishing.

### Other Steps

The method for producing the present treatment liquid may have steps such as a distillation step, a reaction step, and a neutralization step.

### Distillation Step

The distillation step is a step of distilling the purification target substance containing an organic solvent to obtain a distilled purification target substance. The method of distilling the purification target substance is not particularly limited, and a known method can be used. In a typical method, for example, a distillation column is disposed on the upstream side of the purification apparatus used in the filtration step, and the distilled purification target substance is introduced into the production tank.

Here, the liquid-contact portion of the distillation column is preferably, but not necessarily, formed of a corrosion-resistant material as already described.

### Reaction Step

The reaction step is a step of reacting raw materials together to produce a reaction product, that is, the purification target substance containing an organic solvent. The method of producing the purification target substance is not particularly limited, and a known method can be used. In a typical method, for example, a reactor is disposed on the upstream side of the production tank (or the distillation column) of the purification apparatus used in the filtration step, and the reaction product is introduced into the production tank (or the distillation column).

Here, the liquid-contact portion of the production tank is preferably, but not necessarily, formed of a corrosion-resistant material as already described.

### Neutralization Step

The neutralization step is a step of neutralizing the purification target substance to reduce the charge potential of the purification target substance.

The method of neutralization is not particularly limited, and a known neutralization method can be used. An example of the neutralization method is to bring the purification target substance into contact with a conductive material.

The contact time for which the purification target substance is brought into contact with the conductive material is preferably 0.001 to 60 seconds, more preferably 0.001 to 1 second, particularly preferably 0.01 to 0.1 seconds. Examples of the conductive material include stainless steel, gold, platinum, diamond, and glassy carbon.

An example of the method of bringing the purification target substance into contact with the conductive material is to pass the purification target substance through a grounded mesh made of the conductive material, the grounded mesh being disposed inside the conduit.

The purification of the purification target substance, involving opening of a container, washing of the container and apparatus, loading of a solution, analysis, etc., is preferably all performed in a clean room. The clean room is preferably a clean room at a cleanliness level of class 4 or higher defined in International Standard ISO 14644-1: 2015 established by International Organization for Standardization. Specifically, the clean room preferably satisfies any one of ISO class 1, ISO class 2, ISO class 3, and ISO class 4, more preferably satisfies ISO class 1 or ISO class 2, particularly preferably satisfies ISO class 1.

The present treatment liquid may be stored at any temperature, but is preferably stored at 4° C. or higher, at which temperatures impurities and the like contained in trace amounts in the present treatment liquid are less likely to leach out, and as a result the advantageous effects of the present invention are better produced.

In addition to the above steps, a dehydration step may be performed. The dehydration step can be performed using, for example, distillation or a molecular sieve.

### EXAMPLES

The present invention will now be described in more detail with reference to Examples. The materials, amounts, proportions, treatments, treatment sequences, etc. given in the following Examples may be changed as appropriate without departing from the spirit of the present invention. Thus, the scope of the present invention should not be construed as being limited by the Examples given below.

### Components Used to Prepare Treatment Liquid

### Aliphatic Hydrocarbon Solvent

Undecane: Wako Special Grade manufactured by FUJIFILM Wako Pure Chemical Corporation
Decane: Wako Special Grade manufactured by FUJIFILM Wako Pure Chemical Corporation
Dodecane: Wako Special Grade manufactured by FUJIFILM Wako Pure Chemical Corporation
Methyldecane: reagent manufactured by FUJIFILM Wako Pure Chemical Corporation

### Specific Acid Component

Acetic acid: Ultra Pure Chemical from KANTO CHEMICAL CO., INC.
Propionic acid: Wako Special Grade manufactured by FUJIFILM Wako Pure Chemical Corporation
Butyric acid: Wako Special Grade manufactured by FUJIFILM Wako Pure Chemical Corporation
Formic acid: Wako Special Grade manufactured by FUJIFILM Wako Pure Chemical Corporation

### Ester Solvent

Butyl acetate: Wako Special Grade manufactured by FUJIFILM Wako Pure Chemical Corporation
Isobutyl acetate: Wako Special Grade manufactured by FUJIFILM Wako Pure Chemical Corporation
tert-Butyl acetate: Wako Special Grade manufactured by FUJIFILM Wako Pure Chemical Corporation
Amyl acetate: Wako Special Grade manufactured by FUJIFILM Wako Pure Chemical Corporation
Isoamyl acetate: Wako Special Grade manufactured by FUJIFILM Wako Pure Chemical Corporation
Propyl propionate: Wako Special Grade manufactured by FUJIFILM Wako Pure Chemical Corporation
Isopropyl propionate: Wako Special Grade manufactured by FUJIFILM Wako Pure Chemical Corporation
Butyl propionate: Wako Special Grade manufactured by FUJIFILM Wako Pure Chemical Corporation
Isobutyl propionate: Wako Special Grade manufactured by FUJIFILM Wako Pure Chemical Corporation
Ethyl butyrate: Wako Special Grade manufactured by FUJIFILM Wako Pure Chemical Corporation
Ethyl isobutyrate: Wako Special Grade manufactured by FUJIFILM Wako Pure Chemical Corporation
Amyl formate: Wako Special Grade manufactured by FUJIFILM Wako Pure Chemical Corporation
Isoamyl formate: Wako Special Grade manufactured by FUJIFILM Wako Pure Chemical Corporation

### Water

Ultrapure water: sampled from an ultrapure water system manufactured by Nomura Micro Science Co., Ltd.

### Aromatic Hydrocarbon

1,2,3,5-Tetramethylbenzene: reagent manufactured by FUJIFILM Wako Pure Chemical Corporation

### Alcohol

1-Butanol: Wako Special Grade manufactured by FUJIFILM Wako Pure Chemical Corporation

### Specific Metallic Element

Fe: ICPMS standard solution manufactured by FUJIFILM Wako Pure Chemical Corporation
Ni: ICPMS standard solution manufactured by FUJIFILM Wako Pure Chemical Corporation
Cr: ICPMS standard solution manufactured by FUJIFILM Wako Pure Chemical Corporation

### Contents of Components in Treatment Liquid

After the preparation of treatment liquids described later, it was confirmed by the following measurement method that the contents of the components were as shown in Tables below.

### Contents of Aliphatic Hydrocarbon Solvent, Ester Solvent, Specific Acid Component, Aromatic Hydrocarbon, and Alcohol

The contents of an aliphatic hydrocarbon solvent, an ester solvent, a specific acid component, an aromatic hydrocarbon, and an alcohol in a treatment liquid were measured using a gas chromatograph mass spectrometer (product name “GCMS-2020”, manufactured by Shimadzu Corporation).

### Measurement Conditions

Capillary column: InertCap 5MS/NP, 0.25 mm I.D.×30 m, df=0.25 μm
Sample introduction method: split, 75 kPa, constant pressure
Vaporization chamber temperature: 230° C.
Column oven temperature: 80° C. (2 min)—500° C. (13 min); heating rate, 15° C./min
Carrier gas: helium
Septum purge flow rate: 5 mL/min
Split ratio: 25:1
Interface temperature: 250° C.
Ion source temperature: 200° C.
Measurement mode: Scan m/z=85 to 500
Sample introduction volume: 1 μL
Contents of Specific Metallic Elements

The contents of specific metallic elements (Fe, Ni, and Cr) in a treatment liquid (the total content of Fe, Ni, and Cr elements) were measured using Agilent 8900 Triple Quadrupole ICP-MS (for semiconductor analysis, option #200) under the following measurement conditions.

### Measurement Conditions

A sample introduction system including a quartz torch, a coaxial perfluoroalkoxyalkane (PFA) nebulizer (self-priming), and a platinum interface cone was used. The measurement parameters under cool plasma conditions are as follows.
Radio frequency (RF) output (W): 600
Carrier gas flow rate (L/min): 0.7
Make-up gas flow rate (L/min): 1
Sampling depth (mm): 18

For a treatment liquid in which the contents of the specific metallic elements were very small, the measurement was performed after low-temperature evaporation and concentration treatment were performed in advance using a synthetic quartz container, and the measured values were divided by the concentration ratio to determine the contents of the specific metallic elements.

### Content of Water

The content of water (water content) in a treatment liquid was measured using an apparatus (Karl Fischer moisture titrator MKA-610 manufactured by Kyoto Electronics Manufacturing Co., Ltd.) whose measurement principle was based on Karl Fischer water titration.

### First Example

In Examples 1-1 to 1-7, 2-1 to 2-10, 3-1 to 3-2, 4-1 to 4-3, 5-1 to 5-2, and 6-1 to 6-2, treatment liquids were used as developers to perform evaluations.

### Examples 1-1 to 1-7

Using developers of Examples 1-1 to 1-7 having different specific acid component contents, whether the specific acid component content in a developer including an aliphatic hydrocarbon solvent was correlated with variation in line width of a resist pattern was examined.

### Method of Preparing Developer

The developers of Examples 1-1 to 1-7 were prepared in the following manner.

First, organic solvents (an aliphatic hydrocarbon solvent and an ester solvent) were purified through low-temperature distillation in an airtight container made of Teflon (registered trademark) and filter filtration. The purification was repeated until the specific metallic element content (measured by ICP-MS described later) fell below 1 mass ppt.

Next, the purified aliphatic hydrocarbon solvent and ester solvent were mixed such that the contents thereof were as shown in Table below, and components other than the organic solvents were then added such that the contents thereof were as shown in Table 1. In this manner, the developers of Examples 1-1 to 1-7 were obtained.

Here, in the preparation of the developers, all the operations for preparing the components were performed in an ISO class 3 clean booth to prevent contamination. The containers and equipment for use in the preparation of the components and the measurement of, for example, form the contents of the components were selected from those whose liquid-contact portions were made of Teflon (registered trademark), glass, or electropolished stainless steel. The liquid-contact portions were thoroughly washed in advance using FN-DP001 manufactured by FUJIFILM Electronic Materials Co., Ltd. before use.

As the filter used for the filter filtration, a 7 nm PTFE filter manufactured by Nihon Entegris G.K., a 10 nm PE (polyethylene) filter manufactured by Nihon Entegris G.K., and a 5 nm nylon filter manufactured by Nihon Pall Ltd. were used alone or in appropriate combination.

### Preparation of Resist Composition R-1

The following components were mixed to prepare a mixed solution.
Polymer 1 54 parts by mass
Photoacid generator 31 parts by mass
Acid diffusion control agent 15 parts by mass
Propylene glycol monomethyl ether acetate 3430 parts by mass
Propylene glycol monomethyl ether 1470 parts by mass

Polymer 1 was a polymer having the following two repeating units and had a weight-average molecular weight of 8700 and a dispersity (Mw/Mn) of 1.23. The molar ratio between the repeating unit represented by U-01 and the repeating unit represented by U-19 was 1:1.

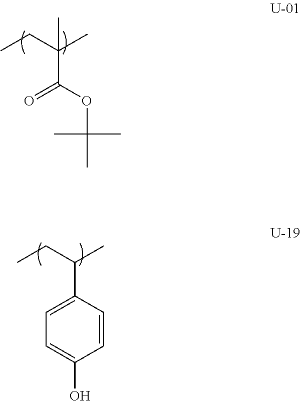

Photoacid generator (see the following structural formula)

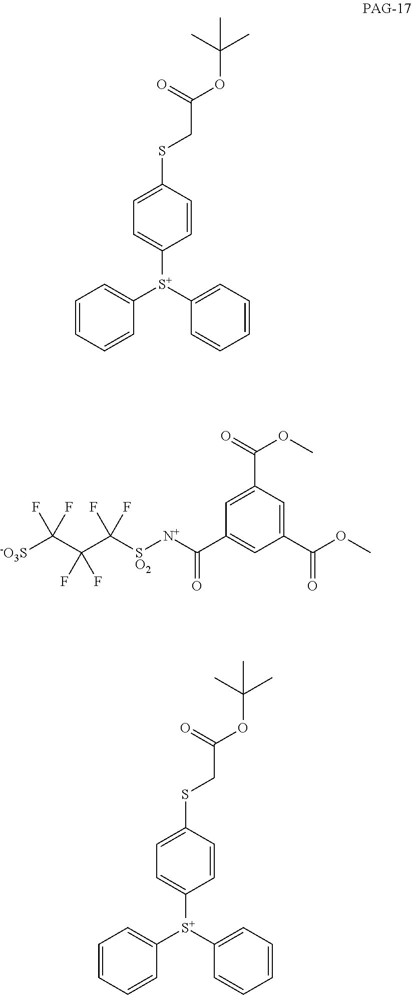

Acid diffusion control agent (see the following structural formula)

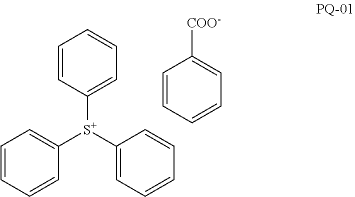

The mixed solution obtained above was then filtered through a polyethylene filter having a pore size of 0.03 μm to prepare a resist composition R-1.

### Examination: Deviation in Line Width

In the following manner, whether variation in line width of a resist pattern varied according to the specific acid component content in a developer was examined.

First, a composition SHB-A940 for underlayer film formation (manufactured by Shin-Etsu Chemical Co., Ltd.) was applied onto a 12-inch silicon wafer and baked at 205° C. for 60 seconds to form an underlayer film having a thickness of 20 nm. The resist composition R-1 prepared above was applied thereto and baked (PB) at 90° C. for 60 seconds to form a resist film having a thickness of 35 nm. Thus, a resist-film-carrying silicon wafer was produced.

The resist-film-carrying silicon wafer obtained was subjected to pattern exposure using an EUV exposure device (Micro Exposure Tool manufactured by Exitech Ltd.; NA, 0.3; Quadrupole; outer sigma, 0.68; inner sigma, 0.36). As a reticle, a photomask having a line size of 22 nm and a line-to-space ratio of 1:1 was used. Thereafter, after baking (PEB) was performed at 100° C. for 60 seconds, development was performed by puddling for 30 seconds using each of the developers of Examples 1-1 to 1-7, and the wafer was rotated at a rotation speed of 4000 rpm for 30 seconds, thereby obtaining a line-and-space pattern with a pitch of 28 to 50 nm.

The pattern obtained was observed and measured for line width at 100 points, and their variation was evaluated in terms of deviation.
A: within ±0.5
B: within ±0.75
C: within ±1.0
D: beyond ±1.0

As shown in Table 1, it has been confirmed that variation in line width of a resist pattern varies according to the specific acid component content in a developer. This has demonstrated that the specific acid component content in a developer is closely related to variation in line width of a resist pattern.

The above examination results suggest that, for example, a resist pattern whose deviation of variation in line width is within ±1.0 can be obtained if the inspection of a developer is performed with the allowable range of the specific acid component content in the developer set to be 2000 mass ppm or less.

TABLE 1

| | | | | | | Ester solvent | | |
|---|---|---|---|---|---|---|---|---|
| | | | | | | | | Ester |
| | | | | | | | | solvent/ |
| | | | | Specific acid | | | | hydro- |
| | | Hydrocarbon | | component | | | | carbon |
| | | solvent | | | Content | | | solvent |
| | | | Content | | (mass | | Content | (mass |
| Table 1 | Use | Type | (mass %) | Type | ppm) | Type | (mass %) | ratio) |
| Example | developer | undecane | 10 | acetic | 3 | butyl | 90 | 9.0 |
| 1-1 | | | | acid | | acetate | | |
| Example | developer | undecane | 10 | acetic | 11 | butyl | 90 | 9.0 |
| 1-2 | | | | acid | | acetate | | |
| Example | developer | undecane | 10 | acetic | 30 | butyl | 90 | 9.0 |
| 1-3 | | | | acid | | acetate | | |
| Example | developer | undecane | 10 | acetic | 400 | butyl | 90 | 9.0 |
| 1-4 | | | | acid | | acetate | | |
| Example | developer | undecane | 10 | acetic | 1200 | butyl | 89.9 | 9.0 |
| 1-5 | | | | acid | | acetate | | |
| Example | developer | undecane | 10 | acetic | 2000 | butyl | 89.8 | 9.0 |
| 1-6 | | | | acid | | acetate | | |
| Example | developer | undecane | 10 | acetic | 5000 | butyl | 89.5 | 9.0 |
| 1-7 | | | | acid | | acetate | | |

| | Aromatic | | | Specific | | | | |
|---|---|---|---|---|---|---|---|---|
| | hydro- | | | metallic element | | | | |
| | carbon | Alcohol | Water | Total | | | | |
| | Content | Content | Content | content | Fe | Cr | Ni | Deviation |
| | (mass | (mass | (mass | (mass | (mass | (mass | (mass | in line |
| Table 1 | ppm) | ppm) | ppm) | ppt) | ppt) | ppt) | ppt) | width |
| Example | 120 | 40 | 87 | 7 | 2 | 3 | 2 | B |
| 1-1 | | | | | | | | |
| Example | 120 | 40 | 87 | 7 | 2 | 3 | 2 | A |
| 1-2 | | | | | | | | |
| Example | 120 | 40 | 87 | 7 | 2 | 3 | 2 | A |
| 1-3 | | | | | | | | |
| Example | 120 | 40 | 87 | 7 | 2 | 3 | 2 | B |
| 1-4 | | | | | | | | |
| Example | 120 | 40 | 87 | 7 | 2 | 3 | 2 | B |
| 1-5 | | | | | | | | |
| Example | 120 | 40 | 87 | 7 | 2 | 3 | 2 | C |
| 1-6 | | | | | | | | |
| Example | 120 | 40 | 87 | 7 | 2 | 3 | 2 | D |
| 1-7 | | | | | | | | |

### Examples 2-1 to 2-10

Using developers of Examples 2-1 to 2-10 in which the mass ratios of the content of an ester solvent to the content of an aliphatic hydrocarbon solvent were different from each other, whether the mass ratio of the content of an ester solvent to the content of an aliphatic hydrocarbon solvent in a developer was correlated with the sensitivity of a resist pattern was examined.

The developers of Examples 2-1 to 2-10 were prepared in the same manner as in Examples 1-1 to 1-7 except that the contents of the components were adjusted so as to be values shown in Table 2.

Furthermore, using each of the developers of Examples 2-1 to 2-10, a pattern was formed on a 12-inch substrate in the same manner as in Examples 1-1 to 1-7.

### Examination: Ratio Relative to Set Sensitivity

In the following manner, whether the ratio relative to set sensitivity varied according to the mass ratio of the content of an ester solvent to the content of an aliphatic hydrocarbon solvent in a developer was examined. Using the optimum exposure dose in Example 1-3 as set sensitivity, sensitivity differences were determined as the ratios of the optimum exposure doses in Examples 2-1 to 2-10 relative to the set sensitivity and evaluated.
A: within ±0.05
B: within ±0.10
C: within ±0.50
D: beyond ±0.50

As shown in Table 2, it has been confirmed that the evaluation results of the ratio relative to set sensitivity vary according to the above mass ratio. This has demonstrated that the above mass ratio in a developer is closely related to the evaluation results of the ratio relative to set sensitivity.

The above examination results suggest that, for example, a developer whose ratio relative to set sensitivity is within ±0.10 can be obtained if the inspection of a developer is performed with the allowable range of the above mass ratio in the developer set to be 8.1 to 10.1.

TABLE 2

| | | | | | | Ester solvent | | |
|---|---|---|---|---|---|---|---|---|
| | | | | | | | | Ester |
| | | | | | | | | solvent/ |
| | | | | Specific acid | | | | hydro- |
| | | Hydrocarbon | | component | | | | carbon |
| | | solvent | | | Content | | | solvent |
| | | | Content | | (mass | | Content | (mass |
| Table 2 | Use | Type | (mass %) | Type | ppm) | Type | (mass %) | ratio) |
| Example | developer | undecane | 8.5 | acetic | 27 | butyl | 91.5 | 10.8 |
| 2-1 | | | | acid | | acetate | | |
| Example | developer | undecane | 9 | acetic | 27 | butyl | 91 | 10.1 |
| 2-2 | | | | acid | | acetate | | |
| Example | developer | undecane | 9.5 | acetic | 29 | butyl | 90.5 | 9.5 |
| 2-3 | | | | acid | | acetate | | |
| Example | developer | undecane | 9.9 | acetic | 30 | butyl | 90.1 | 9.1 |
| 2-4 | | | | acid | | acetate | | |
| Example | developer | undecane | 9.95 | acetic | 30 | butyl | 90.05 | 9.1 |
| 2-5 | | | | acid | | acetate | | |
| Example | developer | undecane | 10.05 | acetic | 30 | butyl | 89.95 | 9.0 |
| 2-6 | | | | acid | | acetate | | |
| Example | developer | undecane | 10.1 | acetic | 30 | butyl | 89.9 | 8.9 |
| 2-7 | | | | acid | | acetate | | |
| Example | developer | undecane | 10.5 | acetic | 31 | butyl | 89.5 | 8.5 |
| 2-8 | | | | acid | | acetate | | |
| Example | developer | undecane | 11 | acetic | 33 | butyl | 89 | 8.1 |
| 2-9 | | | | acid | | acetate | | |
| Example | developer | undecane | 11.5 | acetic | 33 | butyl | 88.5 | 7.7 |
| 2-10 | | | | acid | | acetate | | |

| | Aromatic | | | Specific | | | | |
|---|---|---|---|---|---|---|---|---|
| | hydro- | | | metallic element | | | | |
| | carbon | Alcohol | Water | Total | | | | Ratio |
| | Content | Content | Content | content | Fe | Cr | Ni | relative |
| | (mass | (mass | (mass | (mass | (mass | (mass | (mass | to set |
| Table 2 | ppm) | ppm) | ppm) | ppt) | ppt) | ppt) | ppt) | sensitivity |
| Example | 108 | 40 | 87 | 7 | 2 | 3 | 2 | C |
| 2-1 | | | | | | | | |
| Example | 108 | 40 | 87 | 7 | 2 | 3 | 2 | B |
| 2-2 | | | | | | | | |
| Example | 114 | 40 | 87 | 7 | 2 | 3 | 2 | B |
| 2-3 | | | | | | | | |
| Example | 119 | 40 | 87 | 7 | 2 | 3 | 2 | B |
| 2-4 | | | | | | | | |
| Example | 119 | 40 | 87 | 7 | 2 | 3 | 2 | A |
| 2-5 | | | | | | | | |
| Example | 121 | 40 | 87 | 7 | 2 | 3 | 2 | A |
| 2-6 | | | | | | | | |
| Example | 121 | 40 | 87 | 7 | 2 | 3 | 2 | B |
| 2-7 | | | | | | | | |
| Example | 126 | 40 | 87 | 7 | 2 | 3 | 2 | B |
| 2-8 | | | | | | | | |
| Example | 132 | 40 | 87 | 7 | 2 | 3 | 2 | B |
| 2-9 | | | | | | | | |
| Example | 132 | 40 | 87 | 7 | 2 | 3 | 2 | C |
| 2-10 | | | | | | | | |

### Examples 3-1 to 3-2

Using developers of Examples 3-1 to 3-2 having different aromatic hydrocarbon contents, whether the aromatic hydrocarbon content in a developer was correlated with the bridge defect of a resist pattern was examined.

The developers of Examples 3-1 to 3-2 were prepared in the same manner as in Examples 1-1 to 1-7 except that the contents of the components were adjusted so as to be values shown in Table 3.

### Examination: Bridge Defect

In the following manner, whether the evaluation results of the bridge defect varied according to the aromatic hydrocarbon content in a developer was examined.

The formation of a pattern substrate was performed in the same manner as in Examples 1-1 to 1-7 except that a reticle having a line width (line size) of 28 nm and a line-to-space ratio of 1:1 was used.

For the pattern substrate obtained, the position of defects on the substrate was detected using Uvision 5 (manufactured by AMAT), and the defects were observed using SEMVision G4 (manufactured by AMAT) to evaluate a maximum line width at which the bridge defect started to occur.
A: 15 nm
B: 14 nm
C: 13 nm
D: 12 nm
E: not resolved

As shown in Table 3, it has been confirmed that the evaluation results of the bridge defect vary according to the aromatic hydrocarbon content in a developer. This has demonstrated that the aromatic hydrocarbon content in a developer is closely related to the evaluation results of the bridge defect.

The above examination results suggest that, for example, a resist pattern that does not suffer from a bridge defect until at a line width of 14 nm or more can be obtained if the inspection of a developer is performed with the allowable range of the aromatic hydrocarbon content in the developer set to be 2000 mass ppm or less.

TABLE 3

| | | | | | | Ester solvent | | |
|---|---|---|---|---|---|---|---|---|
| | | | | | | | | Ester |
| | | | | | | | | solvent/ |
| | | | | Specific acid | | | | hydro- |
| | | Hydrocarbon | | component | | | | carbon |
| | | solvent | | | Content | | | solvent |
| | | | Content | | (mass | | Content | (mass |
| Table 3 | Use | Type | (mass %) | Type | ppm) | Type | (mass %) | ratio) |
| Example | developer | undecane | 10 | acetic | 30 | buty | 90 | 9.0 |
| 3-1 | | | | acid | | acetate | | |
| Example | developer | undecane | 10 | acetic | 30 | butyl | 90 | 9.0 |
| 3-2 | | | | acio | | acetate | | |

| | Aromatic | | | Specific | | | | |
|---|---|---|---|---|---|---|---|---|
| | hydro- | | | metallic element | | | | |
| | carbon | Alcohol | Water | Total | | | | |
| | Content | Content | Content | content | Fe | Cr | Ni | |
| | (mass | (mass | (mass | (mass | (mass | (mass | (mass | Bridge |
| Table 3 | ppm) | ppm) | ppm) | ppt) | ppt) | ppt) | ppt) | defect |
| Example | 1500 | 40 | 170 | 28 | 11 | 9 | 8 | B |
| 3-1 | | | | | | | | |
| Example | 3500 | 40 | 170 | 28 | 11 | 9 | 8 | C |
| 3-2 | | | | | | | | |

### Examples 4-1 to 4-3

Using developers of Examples 4-1 to 4-3 having different alcohol contents, whether the alcohol content in a developer was correlated with the coating defect of a resist pattern was examined.

The developers of Examples 4-1 to 4-3 were prepared in the same manner as in Examples 1-1 to 1-7 except that the contents of the components were adjusted so as to be values shown in Table 4.

### Examination: Coating Defect

In the following manner, whether the evaluation results of the coating defect varied according to the alcohol content in a developer was examined.

The developers of Examples 4-1 to 4-3 were each applied onto a 12-inch silicon substrate using a coating device (Lithius Pro Z manufactured by Tokyo Electron Ltd.), and the number of defects before and after the application was counted to evaluate the number of increased defects. For the counting of the number of defects, a surface foreign body inspection apparatus (SP-5 manufactured by KLA-Tencor) was used to evaluate foreign bodies having a diameter of 17 nm or more.
A: 50 or less/substrate
B: 51 to 100/substrate
C: 101 to 300/substrate
D: 301 to 1,000/substrate
E: more than 1,000/substrate

As shown in Table 4, it has been confirmed that the evaluation results of the coating defect vary according to the alcohol content in a developer. This has demonstrated that the alcohol content in a developer is closely related to the evaluation results of the coating defect.

The above examination results suggest that, for example, a developer that causes 100 or less coating defects can be used if the developer is inspected with the allowable range of the alcohol content in the developer set to be 5000 mass ppm or less.

TABLE 4

| | | | | | | Ester solvent | | |
|---|---|---|---|---|---|---|---|---|
| | | | | | | | | Ester |
| | | | | | | | | solvent/ |
| | | | | Specific acid | | | | hydro- |
| | | Hydrocarbon | | component | | | | carbon |
| | | solvent | | | Content | | | solvent |
| | | | Content | | (mass | | Content | (mass |
| Table 4 | Use | Type | (mass %) | Type | ppm) | Type | (mass %) | ratio) |
| Example | developer | undecane | 10 | acetic | 400 | butyl | 90 | 9.0 |
| 4-1 | | | | acid | | acetate | | |
| Example | developer | undecane | 10 | acetic | 600 | butyl | 90 | 9.0 |
| 4-2 | | | | acid | | acetate | | |
| Example | developer | undecane | 10 | acetic | 30 | butyl | 90 | 9.0 |
| 4-3 | | | | acid | | acetate | | |

| | Aromatic | | | Specific | | | | |
|---|---|---|---|---|---|---|---|---|
| | hydro- | | | metallic element | | | | |
| | carbon | Alcohol | Water | Total | | | | |
| | Content | Content | Content | content | Fe | Cr | Ni | |
| | (mass | (mass | (mass | (mass | (mass | (mass | (mass | Coating |
| Table 4 | ppm) | ppm) | ppm) | ppt) | ppt) | ppt) | ppt) | defect |
| Example | 120 | 4000 | 130 | 42 | 23 | 8 | 11 | B |
| 4-1 | | | | | | | | |
| Example | 120 | 7000 | 150 | 51 | 31 | 11 | 9 | C |
| 4-2 | | | | | | | | |
| Example | 120 | 5 | 87 | 7 | 2 | 3 | 2 | A |
| 4-3 | | | | | | | | |

### Examples 5-1 to 5-2

Using developers of Examples 5-1 to 5-2 having different water contents, whether the water content in a developer was correlated with the pattern collapse of a resist pattern was examined.

The developers of Examples 5-1 to 5-2 were prepared in the same manner as in Examples 1-1 to 1-7 except that the contents of the components were adjusted so as to be values shown in Table 5.

### Examination: Pattern Collapse

In the following manner, whether the evaluation results of pattern collapse varied according to the water content in a developer was examined.

The formation of a pattern substrate was performed in the same manner as in Examples 1-1 to 1-7 except that a reticle having a line width (line size) of 28 nm and a line-to-space ratio of 1:1 was used.

For the pattern substrate obtained, the position of defects on the substrate was detected using Uvision 5 (manufactured by AMAT), and the defects were observed using SEMVision G4 (manufactured by AMAT) to evaluate a minimum line width at which the pattern collapse defect started to occur.
A: 12 nm or less
B: more than 12 nm and 14 nm or less
C: more than 14 nm and 16 nm or less
D: more than 16 nm

As shown in Table 5, it has been confirmed that the evaluation results of pattern collapse vary according to the water content in a developer. This has demonstrated that the water content in a developer is closely related to the evaluation results of pattern collapse.

The above examination results suggest that, for example, a resist pattern whose evaluation result of pattern collapse is 14 nm or less can be obtained if the inspection of a developer is performed with the allowable range of the water content in the developer set to be 1000 mass ppm or less.

TABLE 5

| | | | | | | Ester solvent | | |
|---|---|---|---|---|---|---|---|---|
| | | | | | | | | Ester |
| | | | | | | | | solvent/ |
| | | | | Specific acid | | | | hydro- |
| | | Hydrocarbon | | component | | | | carbon |
| | | solvent | | | Content | | | solvent |
| | | | Content | | (mass | | Content | (mass |
| Table 5 | Use | Type | (mass %) | Type | ppm) | Type | (mass %) | ratio) |
| Example | developer | undecane | 10 | acetic | 30 | butyl | 90 | 9.0 |
| 5-1 | | | | acid | | acetate | | |
| Example | developer | undecane | 10 | acetic | 30 | butyl | 90 | 9.0 |
| 5-2 | | | | acid | | acetate | | |

| | Aromatic | | | Specific | | | | |
|---|---|---|---|---|---|---|---|---|
| | hydro- | | | metallic element | | | | |
| | carbon | Alcohol | Water | Total | | | | |
| | Content | Content | Content | content | Fe | Cr | Ni | |
| | (mass | (mass | (mass | (mass | (mass | (mass | (mass | Pattern |
| Table 5 | ppm) | ppm) | ppm) | ppt) | ppt) | ppt) | ppt) | collapse |
| Example | 120 | 40 | 980 | 7 | 2 | 3 | 2 | B |
| 5-1 | | | | | | | | |
| Example | 120 | 40 | 2000 | 7 | 2 | 3 | 2 | C |
| 5-2 | | | | | | | | |

### Examples 6-1 to 6-2

Using developers of Examples 6-1 to 6-2 having different specific metallic element contents, whether the specific metallic element content in a developer was correlated with the metal-containing defect of a resist pattern was examined.

The developers of Examples 6-1 to 6-2 were prepared in the same manner as in Examples 1-1 to 1-7 except that the contents of the components were adjusted so as to be values shown in Table 6.

### Examination: Metal-Containing Defect

In the following manner, whether the evaluation results of the metal-containing defect varied according to the specific metallic element content in a developer was examined.

The developers of Examples 6-1 to 6-2 were each applied onto a 12-inch silicon substrate using a coating device (Lithius Pro Z manufactured by Tokyo Electron Ltd.), and foreign bodies having a diameter of 17 nm or more were measured for their defect position before and after the application using a surface foreign body inspection apparatus (SP-5 manufactured by KLA-Tencor). Defects increased by the application were subjected to a contained element analysis with a review SEM (SEMVision G6 manufactured by AMAT), and the number of defects containing metallic components was counted to perform an evaluation.
A: 2 or less/substrate
B: 3 to 5/substrate
C: 6 to 10/substrate
D: 11 to 30/substrate
E: more than 30/substrate

As shown in Table 6, it has been confirmed that the evaluation results of the metal-containing defect vary according to the specific metallic element content in a developer. This has demonstrated that the specific metallic element content in a developer is closely related to the evaluation results of the metal-containing defect.

The above examination results suggest that, for example, a resist pattern having 10 or less metal-containing defects can be obtained if the inspection of a developer is performed with the allowable range of the specific metallic element content in the developer set to be 100 mass ppt or less.

TABLE 6

| | | | | | | Ester solvent | | |
|---|---|---|---|---|---|---|---|---|
| | | | | | | | | Ester |
| | | | | | | | | solvent/ |
| | | | | Specific acid | | | | hydro- |
| | | Hydrocarbon | | component | | | | carbon |
| | | solvent | | | Content | | | solvent |
| | | | Content | | (mass | | Content | (mass |
| Table 6 | Use | Type | (mass %) | Type | ppm) | Type | (mass %) | ratio) |
| Example | developer | undecane | 10 | acetic | 30 | butyl | 90 | 9.0 |
| 6-1 | | | | acid | | acetate | | |
| Example | developer | undecane | 10 | acetic | 30 | butyl | 90 | 9.0 |
| 6-2 | | | | acid | | acetate | | |

| | Aromatic | | | Specific | | | | |
|---|---|---|---|---|---|---|---|---|
| | hydro- | | | metallic element | | | | |
| | carbon | Alcohol | Water | Total | | | | Metal- |
| | Content | Content | Content | content | Fe | Cr | Ni | containing |
| | (mass | (mass | (mass | (mass | (mass | (mass | (mass | coating |
| Table 6 | ppm) | ppm) | ppm) | ppt) | ppt) | ppt) | ppt) | defect |
| Example | 120 | 40 | 87 | 83 | 33 | 29 | 21 | C |
| 6-1 | | | | | | | | |
| Example | 120 | 40 | 87 | 112 | 53 | 31 | 28 | D |
| 6-2 | | | | | | | | |

### Second Example

In Examples 7-1 to 7-7, Examples 8-1 to 8-10, Examples 9-1 to 9-2, Examples 10-1 to 10-3, Examples 11-1 to 11-2, and Examples 12-1 to 12-2, treatment liquids were used as rinsing liquids to perform evaluations.

### Examples 7-1 to 7-7

Using rinsing liquids of Examples 7-1 to 7-7 having different specific acid component contents, whether the specific acid component content in a rinsing liquid including an aliphatic hydrocarbon solvent was correlated with variation in line width of a resist pattern was examined.

The rinsing liquids of Examples 7-1 to 7-7 were prepared in the same manner as in Examples 1-1 to 1-7 except that the contents of the components were adjusted so as to be values shown in Table 7.

### Examination: Deviation in Line Width

The same examination as in Examples 1-1 to 1-7 was performed except for using a line-and-space pattern obtained by the following procedure: butyl acetate was used as a developer, and after the development, a wafer, while being rotated at a rotation speed of 1000 rpm, was rinsed by pouring each of the rinsing liquids of Examples 7-1 to 7-7 over the wafer for 10 seconds, and the wafer was then rotated at a rotation speed of 3000 rpm for 30 seconds.

As shown in Table 7, it has been confirmed that variation in line width of a resist pattern varies according to the specific acid component content in a rinsing liquid. This has demonstrated that the specific acid component content in a rinsing liquid is closely related to variation in line width of a resist pattern.

The above examination results suggest that, for example, a resist pattern whose deviation of variation in line width is within ±1.0 can be obtained if the inspection of a treatment liquid is performed with the allowable range of the specific acid component content in the rinsing liquid set to be 2000 mass ppm or less.

TABLE 7

| | | | | | | Ester solvent | | |
|---|---|---|---|---|---|---|---|---|
| | | | | | | | | Ester |
| | | | | | | | | solvent/ |
| | | | | Specific acid | | | | hydro- |
| | | Hydrocarbon | | component | | | | carbon |
| | | solvent | | | Content | | | solvent |
| | | | Content | | (mass | | Content | (mass |
| Table 7 | Use | Type | (mass %) | Type | ppm) | Type | (mass %) | ratio) |
| Example | rinsing | undecane | 10 | acetic | 3 | butyl | 90 | 9.0 |
| 7-1 | liquid | | | acid | | acetate | | |
| Example | rinsing | undecane | 10 | acetic | 11 | butyl | 90 | 9.0 |
| 7-2 | liquid | | | acid | | acetate | | |
| Example | rinsing | undecane | 10 | acetic | 30 | butyl | 90 | 9.0 |
| 7-3 | liquid | | | acid | | acetate | | |
| Example | rinsing | undecane | 10 | acetic | 400 | butyl | 90 | 9.0 |
| 7-4 | liquid | | | acid | | acetate | | |
| Example | rinsing | undecane | 10 | acetic | 1200 | butyl | 89.9 | 9.0 |
| 7-5 | liquid | | | acid | | acetate | | |
| Example | rinsing | undecane | 10 | acetic | 2000 | butyl | 89.8 | 9.0 |
| 7-6 | liquid | | | acid | | acetate | | |
| Example | rinsing | undecane | 10 | acetic | 5000 | butyl | 89.5 | 9.0 |
| 7-7 | liquid | | | acid | | acetate | | |

| | Aromatic | | | Specific | | | | |
|---|---|---|---|---|---|---|---|---|
| | hydro- | | | metallic element | | | | |
| | carbon | Alcohol | Water | Total | | | | |
| | Content | Content | Content | content | Fe | Cr | Ni | Deviation |
| | (mass | (mass | (mass | (mass | (mass | (mass | (mass | in line |
| Table 7 | ppm) | ppm) | ppm) | ppt) | ppt) | ppt) | ppt) | width |
| Example | 120 | 40 | 87 | 7 | 2 | 3 | 2 | C |
| 7-1 | | | | | | | | |
| Example | 120 | 40 | 87 | 7 | 2 | 3 | 2 | B |
| 7-2 | | | | | | | | |
| Example | 120 | 40 | 87 | 7 | 2 | 3 | 2 | B |
| 7-3 | | | | | | | | |
| Example | 120 | 40 | 87 | 7 | 2 | 3 | 2 | C |
| 7-4 | | | | | | | | |
| Example | 120 | 40 | 87 | 7 | 2 | 3 | 2 | C |
| 7-5 | | | | | | | | |
| Example | 120 | 40 | 87 | 7 | 2 | 3 | 2 | C |
| 7-6 | | | | | | | | |
| Example | 120 | 40 | 87 | 7 | 2 | 3 | 2 | D |
| 7-7 | | | | | | | | |

### Examples 8-1 to 8-10

Using rinsing liquids of Examples 8-1 to 8-10 in which the mass ratios of the content of an ester solvent to the content of an aliphatic hydrocarbon solvent were different from each other, whether the mass ratio of the content of an ester solvent to the content of an aliphatic hydrocarbon solvent in a rinsing liquid was correlated with the sensitivity of a resist pattern was examined.

The rinsing liquids of Examples 8-1 to 8-10 were prepared in the same manner as in Examples 1-1 to 1-7 except that the contents of the components were adjusted so as to be values shown in Table 8.

### Examination: Ratio Relative to Set Sensitivity

Pattern substrates were obtained in the same manner as in Examples 2-1 to 2-10 except for using a line-and-space pattern obtained by the following procedure: butyl acetate was used as a developer, and after the development, a wafer, while being rotated at a rotation speed of 1000 rpm, was rinsed by pouring each of the rinsing liquids of Examples 8-1 to 8-10 over the wafer for 10 seconds, and the wafer was then rotated at a rotation speed of 3000 rpm for 30 seconds. The same examination as in Examples 2-1 to 2-10 was performed except that the pattern substrates obtained were used.

Here, the sensitivity in Example 7-3 was used as set sensitivity, and sensitivity differences from the set sensitivity were determined as ratios and evaluated.

As shown in Table 8, it has been confirmed that the evaluation results of the ratio relative to set sensitivity vary according to the above mass ratio. This has demonstrated that the above mass ratio in a rinsing liquid is closely related to the evaluation results of the ratio relative to set sensitivity.

The above examination results suggest that, for example, a resist pattern whose ratio relative to set sensitivity is within ±0.10 can be obtained if the inspection of a rinsing liquid is performed with the allowable range of the above mass ratio in the rinsing liquid set to be 8.1 to 10.1.

TABLE 8

| | | | | | | Ester solvent | | |
|---|---|---|---|---|---|---|---|---|
| | | | | | | | | Ester |
| | | | | | | | | solvent/ |
| | | | | Specific acid | | | | hydro- |
| | | Hydrocarbon | | component | | | | carbon |
| | | solvent | | | Content | | | solvent |
| | | | Content | | (mass | | Content | (mass |
| Table 8 | Use | Type | (mass %) | Type | ppm) | Type | (mass %) | ratio) |
| Example | rinsing | undecane | 8.5 | acetic | 27 | butyl | 91.5 | 10.8 |
| 8-1 | liquid | | | acid | | acetate | | |
| Example | rinsing | undecane | 9 | acetic | 27 | butyl | 91 | 10.1 |
| 8-2 | liquid | | | acid | | acetate | | |
| Example | rinsing | undecane | 9.5 | acetic | 29 | butyl | 90.5 | 9.5 |
| 8-3 | liquid | | | acid | | acetate | | |
| Example | rinsing | undecane | 9.9 | acetic | 30 | butyl | 90.1 | 9.1 |
| 8-4 | liquid | | | acid | | acetate | | |
| Example | rinsing | undecane | 9.95 | acetic | 30 | butyl | 90.05 | 9.1 |
| 8-5 | liquid | | | acid | | acetate | | |
| Example | rinsing | undecane | 10.05 | acetic | 30 | butyl | 89.95 | 9.0 |
| 8-6 | liquid | | | acid | | acetate | | |
| Example | rinsing | undecane | 10.1 | acetic | 30 | butyl | 89.9 | 8.9 |
| 8-7 | liquid | | | acid | | acetate | | |
| Example | rinsing | undecane | 10.5 | acetic | 31 | butyl | 89.5 | 8.5 |
| 8-8 | liquid | | | acid | | acetate | | |
| Example | rinsing | undecane | 11 | acetic | 33 | butyl | 89 | 8.1 |
| 8-9 | liquid | | | acid | | acetate | | |
| Example | rinsing | undecane | 11.5 | acetic | 33 | butyl | 88.5 | 7.7 |
| 8-10 | liquid | | | acid | | acetate | | |

| | Aromatic | | | Specific | | | | |
|---|---|---|---|---|---|---|---|---|
| | hydro- | | | metallic element | | | | |
| | carbon | Alcohol | Water | Total | | | | Ratio |
| | Content | Content | Content | content | Fe | Cr | Ni | relative to |
| | (mass | (mass | (mass | (mass | (mass | (mass | (mass | set |
| Table 8 | ppm) | ppm) | ppm) | ppt) | ppt) | ppt) | ppt) | sensitivity |
| Example | 108 | 40 | 87 | 7 | 2 | 3 | 2 | B |
| 8-1 | | | | | | | | |
| Example | 108 | 40 | 87 | 7 | 2 | 3 | 2 | A |
| 8-2 | | | | | | | | |
| Example | 114 | 40 | 87 | 7 | 2 | 3 | 2 | A |
| 8-3 | | | | | | | | |
| Example | 119 | 40 | 87 | 7 | 2 | 3 | 2 | A |
| 8-4 | | | | | | | | |
| Example | 119 | 40 | 87 | 7 | 2 | 3 | 2 | A |
| 8-5 | | | | | | | | |
| Example | 121 | 40 | 87 | 7 | 2 | 3 | 2 | A |
| 8-6 | | | | | | | | |
| Example | 121 | 40 | 87 | 7 | 2 | 3 | 2 | A |
| 8-7 | | | | | | | | |
| Example | 126 | 40 | 87 | 7 | 2 | 3 | 2 | A |
| 8-8 | | | | | | | | |
| Example | 132 | 40 | 87 | 7 | 2 | 3 | 2 | A |
| 8-9 | | | | | | | | |
| Example | 132 | 40 | 87 | 7 | 2 | 3 | 2 | B |
| 8-10 | | | | | | | | |

### Examples 9-1 to 9-2

Using rinsing liquids of Examples 9-1 to 9-2 having different aromatic hydrocarbon contents, whether the aromatic hydrocarbon content in a rinsing liquid was correlated with the bridge defect of a resist pattern was examined.

The rinsing liquids of Examples 9-1 to 9-2 were prepared in the same manner as in Examples 1-1 to 1-7 except that the contents of the components were adjusted so as to be values shown in Table 9.

### Examination: Bridge Defect

Pattern substrates were obtained in the same manner as in Examples 3-1 to 3-2 except for using a line-and-space pattern obtained by the following procedure: butyl acetate was used as a developer, and after the development, a wafer, while being rotated at a rotation speed of 1000 rpm, was rinsed by pouring each of the rinsing liquids of Examples 9-1 to 9-2 over the wafer for 10 seconds, and the wafer was then rotated at a rotation speed of 3000 rpm for 30 seconds. The same examination as in Examples 3-1 to 3-2 was performed except that the pattern substrates obtained were used.

As shown in Table 9, it has been confirmed that the evaluation results of the bridge defect vary according to the aromatic hydrocarbon content in a rinsing liquid. This has demonstrated that the aromatic hydrocarbon content in a rinsing liquid is closely related to the evaluation results of the bridge defect.

The above examination results suggest that, for example, a resist pattern that does not suffer from a bridge defect until at a line width of 14 nm or more can be obtained if the inspection of a rinsing liquid is performed with the allowable range of the aromatic hydrocarbon content in the rinsing liquid set to be 2000 mass ppm or less.

TABLE 9

| | | | | | | Ester solvent | | |
|---|---|---|---|---|---|---|---|---|
| | | | | | | | | Ester |
| | | | | | | | | solvent/ |
| | | | | Specific acid | | | | hydro- |
| | | Hydrocarbon | | component | | | | carbon |
| | | solvent | | | Content | | | solvent |
| | | | Content | | (mass | | Content | (mass |
| Table 9 | Use | Type | (mass %) | Type | ppm) | Type | (mass %) | ratio) |
| Example | rinsing | undecane | 10 | acetic | 30 | butyl | 90 | 9.0 |
| 9-1 | liquid | | | acid | | acetate | | |
| Example | rinsing | undecane | 10 | acetic | 30 | butyl | 90 | 9.0 |
| 9-2 | liquid | | | acid | | acetate | | |

| | Aromatic | | | Specific | | | | |
|---|---|---|---|---|---|---|---|---|
| | hydro- | | | metallic element | | | | |
| | carbon | Alcohol | Water | Total | | | | |
| | Content | Content | Content | content | Fe | Cr | Ni | |
| | (mass | (mass | (mass | (mass | (mass | (mass | (mass | Bridge |
| Table 9 | ppm) | ppm) | ppm) | ppt) | ppt) | ppt) | ppt) | defect |
| Example | 1500 | 40 | 170 | 28 | 11 | 9 | 8 | C |
| 9-1 | | | | | | | | |
| Example | 3500 | 40 | 170 | 28 | 11 | 9 | 8 | D |
| 9-2 | | | | | | | | |

### Examples 10-1 to 10-3

Using rinsing liquids of Examples 10-1 to 10-3 having different alcohol contents, whether the alcohol content in a rinsing liquid was correlated with the coating defect of a resist pattern was examined.

The rinsing liquids of Examples 10-1 to 10-3 were prepared in the same manner as in Examples 1-1 to 1-7 except that the contents of the components were adjusted so as to be values shown in Table 10.

### Examination: Coating Defect

The same examination as in Examples 4-1 to 4-3 was performed except that the rinsing liquids of Examples 10-1 to 10-3 were used.

As shown in Table 10, it has been confirmed that the evaluation results of the coating defect vary according to the alcohol content in a rinsing liquid. This has demonstrated that the alcohol content in a rinsing liquid is closely related to the evaluation results of the coating defect.

The above examination results suggest that, for example, a resist pattern having 100 or less coating defects can be obtained if the inspection of a rinsing liquid is performed with the allowable range of the alcohol content in the rinsing liquid set to be 5000 mass ppm or less.

TABLE 10

| | | | | | | Ester solvent | | |
|---|---|---|---|---|---|---|---|---|
| | | | | | | | | Ester |
| | | | | | | | | solvent/ |
| | | | | Specific acid | | | | hydro- |
| | | Hydrocarbon | | component | | | | carbon |
| | | solvent | | | Content | | | solvent |
| | | | Content | | (mass | | Content | (mass |
| Table 10 | Use | Type | (mass %) | Type | ppm) | Type | (mass %) | ratio) |
| Example | rinsing | undecane | 10 | acetic | 400 | butyl | 90 | 9.0 |
| 10-1 | liquid | | | acid | | acetate | | |
| Example | rinsing | undecane | 10 | acetic | 600 | butyl | 90 | 9.0 |
| 10-2 | liquid | | | acid | | acetate | | |
| Example | rinsing | undecane | 10 | acetic | 30 | butyl | 90 | 9.0 |
| 10-3 | liquid | | | acid | | acetate | | |

| | Aromatic | | | Specific | | | | |
|---|---|---|---|---|---|---|---|---|
| | hydro- | | | metallic element | | | | |
| | carbon | Alcohol | Water | Total | | | | |
| | Content | Content | Content | content | Fe | Cr | Ni | |
| | (mass | (mass | (mass | (mass | (mass | (mass | (mass | Coating |
| Table 10 | ppm) | ppm) | ppm) | ppt) | ppt) | ppt) | ppt) | defect |
| Example | 120 | 4000 | 130 | 42 | 23 | 8 | 11 | B |
| 10-1 | | | | | | | | |
| Example | 120 | 7000 | 150 | 51 | 31 | 11 | 9 | C |
| 10-2 | | | | | | | | |
| Example | 120 | 5 | 87 | 7 | 2 | 3 | 2 | A |
| 10-3 | | | | | | | | |

### Examples 11-1 to 11-2

Using rinsing liquids of Examples 11-1 to 11-2 having different water contents, whether the water content in a rinsing liquid was correlated with the pattern collapse of a resist pattern was examined.

The rinsing liquids of Examples 11-1 to 11-2 were prepared in the same manner as in Examples 1-1 to 1-7 except that the contents of the components were adjusted so as to be values shown in Table 11.

### Examination: Pattern Collapse

Pattern substrates were obtained in the same manner as in Examples 5-1 to 5-2 except for using a line-and-space pattern obtained by the following procedure: butyl acetate was used as a developer, and after the development, a wafer, while being rotated at a rotation speed of 1000 rpm, was rinsed by pouring each of the rinsing liquids of Examples 11-1 to 11-2 over the wafer for 10 seconds, and the wafer was then rotated at a rotation speed of 3000 rpm for 30 seconds. The same examination as in Examples 5-1 to 5-2 was performed except that the pattern substrates obtained were used.

As shown in Table 11, it has been confirmed that the evaluation results of pattern collapse vary according to the water content in a rinsing liquid. This has demonstrated that the water content in a rinsing liquid is closely related to the evaluation results of pattern collapse.

The above examination results suggest that, for example, a resist pattern whose evaluation result of pattern collapse is 14 nm can be obtained if the inspection of a rinsing liquid is performed with the allowable range of the water content in the rinsing liquid set to be 1000 mass ppm or less.

TABLE 11

| | | | | | | Ester solvent | | |
|---|---|---|---|---|---|---|---|---|
| | | | | | | | | Ester |
| | | | | | | | | solvent/ |
| | | | | Specific acid | | | | hydro- |
| | | Hydrocarbon | | component | | | | carbon |
| | | solvent | | | Content | | | solvent |
| | | | Content | | (mass | | Content | (mass |
| Table 11 | Use | Type | (mass %) | Type | ppm) | Type | (mass %) | ratio) |
| Example | rinsing | undecane | 10 | acetic | 30 | butyl | 90 | 9.0 |
| 11-1 | liquid | | | acid | | acetate | | |
| Example | rinsing | undecane | 10 | acetic | 30 | butyl | 90 | 9.0 |
| 11-2 | liquid | | | acid | | acetate | | |

| | Aromatic | | | Specific | | | | |
|---|---|---|---|---|---|---|---|---|
| | hydro- | | | metallic element | | | | |
| | carbon | Alcohol | Water | Total | | | | |
| | Content | Content | Content | content | Fe | Cr | Ni | |
| | (mass | (mass | (mass | (mass | (mass | (mass | (mass | Pattern |
| Table 11 | ppm) | ppm) | ppm) | ppt) | ppt) | ppt) | ppt) | collapse |
| Example | 120 | 40 | 980 | 7 | 2 | 3 | 2 | C |
| 11-1 | | | | | | | | |
| Example | 120 | 40 | 2000 | 7 | 2 | 3 | 2 | C |
| 11-2 | | | | | | | | |

### Examples 12-1 to 12-2

Using rinsing liquids of Examples 12-1 to 12-2 having different specific metallic element contents, whether the specific metallic element content in a rinsing liquid was correlated with the metal-containing defect of a resist pattern was examined.

The rinsing liquids of Examples 12-1 to 12-2 were prepared in the same manner as in Examples 1-1 to 1-7 except that the contents of the components were adjusted so as to be values shown in Table 12.

### Examination: Metal-Containing Defect

The same examination as in Examples 6-1 to 6-2 was performed except that the rinsing liquids of Examples 12-1 to 12-2 were used.

As shown in Table 12, it has been confirmed that the evaluation results of the metal-containing defect vary according to the specific metallic element content in a rinsing liquid. This has demonstrated that the specific metallic element content in a rinsing liquid is closely related to the evaluation results of the metal-containing defect.

The above examination results suggest that, for example, a resist pattern having 10 or less metal-containing defects can be obtained if the inspection of a rinsing liquid is performed with the allowable range of the specific metallic element content in the rinsing liquid set to be 100 mass ppt or less.

TABLE 12

| | | | | | | Ester solvent | | |
|---|---|---|---|---|---|---|---|---|
| | | | | | | | | Ester |
| | | | | | | | | solvent/ |
| | | | | Specific acid | | | | hydro- |
| | | Hydrocarbon | | component | | | | carbon |
| | | solvent | | | Content | | | solvent |
| | | | Content | | (mass | | Content | (mass |
| Table 12 | Use | Type | (mass % | Type | ppm) | Type | (mass %) | ratio) |
| Example | rinsing | undecane | 10 | acetic | 30 | butyl | 90 | 9.0 |
| 12-1 | liquid | | | acid | | acetate | | |
| Example | rinsing | undecane | 10 | acetic | 30 | butyl | 90 | 9.0 |
| 12-2 | liquid | | | acid | | acetate | | |

| | Aromatic | | | Specific | | | | |
|---|---|---|---|---|---|---|---|---|
| | hydro- | | | metallic element | | | | |
| | carbon | Alcohol | Water | Total | | | | Metal- |
| | Content | Content | Content | content | Fe | Cr | Ni | containing |
| | (mass | (mass | (mass | (mass | (mass | (mass | (mass | coating |
| Table 12 | ppm) | ppm) | ppm) | ppt | ppt) | ppt) | ppt) | defect |
| Example | 120 | 40 | 87 | 83 | 33 | 29 | 21 | C |
| 12-1 | | | | | | | | |
| Example | 120 | 40 | 87 | 112 | 53 | 31 | 28 | D |
| 12-2 | | | | | | | | |

The same examinations as in Examples 7-1 to 7-7, Examples 8-1 to 8-10, Examples 9-1 to 9-2, Examples 10-1 to 10-3, Examples 11-1 to 11-2, and Examples 12-1 to 12-2 were performed except that the combination of an aliphatic hydrocarbon solvent, a specific acid component, and an ester solvent was changed as shown in Table 13. The same tendency as in each Example was exhibited.

TABLE 13

| | Hydrocarbon | Specific acid | Ester |
|---|---|---|---|
| | solvent | component | solvent |
| Table 13 | Type | Type | Type |
| Combination 1 | undecane | acetic acid | isobutyl acetate |
| Combination 2 | undecane | acetic acid | tert-butyl acetate |
| Combination 3 | undecane | acetic acid | amyl acetate |
| Combination 4 | undecane | acetic acid | isoamyl acetate |
| Combination 5 | undecane | propionic acid | propyl propionate |
| Combination 6 | undecane | propionic acid | isopropyl propionate |
| Combination 7 | undecane | propionic acid | butyl propionate |
| Combination 8 | undecane | propionic acid | isobutyl propionate |
| Combination 9 | undecane | butyric acid | ethyl butyrate |
| Combination 10 | undecane | butyric acid | ethyl isobutyrate |
| Combination 11 | undecane | formic acid | amyl formate |
| Combination 12 | undecane | formic acid | isoamyl formate |
| Combination 13 | decane | formic acid | isoamyl formate |
| Combination 14 | dodecane | formic acid | isoamyl formate |
| Combination 15 | methyldecane | formic acid | isoamyl formate |

What is claimed is:

1. A method for inspecting a treatment liquid including an aliphatic hydrocarbon solvent, the method comprising:
a step A1 of acquiring measurement data of a content of an acid component in the treatment liquid, the acid component being at least one selected from the group consisting of carboxylic acids having a hydrocarbon group having 1 to 3 carbon atoms and formic acid; and
a step A2 of determining whether the measurement data acquired in the step A1 falls within a preset allowable range.

2. The method for inspecting a treatment liquid according to claim 1, wherein the aliphatic hydrocarbon solvent includes at least one selected from the group consisting of nonane, decane, undecane, dodecane, and methyldecane.

3. The method for inspecting a treatment liquid according to claim 1, wherein the aliphatic hydrocarbon solvent is undecane.

4. The method for inspecting a treatment liquid according to claim 1, wherein the acid component is acetic acid.

5. The method for inspecting a treatment liquid according to claim 1, wherein the content of the acid component is 1 to 2000 mass ppm relative to a total mass of the treatment liquid.

6. The method for inspecting a treatment liquid according to claim 1, comprising:
a step B1 of acquiring measurement data of a mass ratio of a content of an ester solvent to a content of the aliphatic hydrocarbon solvent in the treatment liquid; and
a step B2 of determining whether the measurement data acquired in the step B1 falls within a preset allowable range.

7. The method for inspecting a treatment liquid according to claim 6, wherein the ester solvent includes at least one selected from the group consisting of butyl acetate, isobutyl acetate, tert-butyl acetate, amyl acetate, isoamyl acetate, propyl propionate, isopropyl propionate, butyl propionate, isobutyl propionate, ethyl butyrate, ethyl isobutyrate, amyl formate, and isoamyl formate.

8. The method for inspecting a treatment liquid according to claim 6, wherein the ester solvent is butyl acetate.

9. The method for inspecting a treatment liquid according to claim 1, comprising:
a step C1 of acquiring measurement data of a content of an aromatic hydrocarbon in the treatment liquid; and
a step C2 of determining whether the measurement data acquired in the step C1 falls within a preset allowable range.

10. The method for inspecting a treatment liquid according to claim 9, wherein the content of the aromatic hydrocarbon is 1 to 2000 mass ppm relative to a total mass of the treatment liquid.

11. The method for inspecting a treatment liquid according to claim 1, comprising:
a step D1 of acquiring measurement data of a content of an alcohol in the treatment liquid; and
a step D2 of determining whether the measurement data acquired in the step D1 falls within a preset allowable range.

12. The method for inspecting a treatment liquid according to claim 11, wherein the content of the alcohol is 1 to 5000 mass ppm relative to a total mass of the treatment liquid.

13. The method for inspecting a treatment liquid according to claim 1, comprising:
a step E1 of acquiring measurement data of a content of water in the treatment liquid; and
a step E2 of determining whether the measurement data acquired in the step E1 falls within a preset allowable range.

14. The method for inspecting a treatment liquid according to claim 13, wherein the content of the water is 1 to 1000 mass ppm relative to a total mass of the treatment liquid.

15. The method for inspecting a treatment liquid according to claim 1, comprising:
a step F1 of acquiring measurement data of a content of a metallic element in the treatment liquid, the metallic element being at least one selected from the group consisting of Fe, Ni, and Cr; and
a step F2 of determining whether the measurement data acquired in the step F1 falls within a preset allowable range.

16. The method for inspecting a treatment liquid according to claim 15, wherein the content of the metallic element is 0.03 to 100 mass ppt relative to a total mass of the treatment liquid.

17. The method for inspecting a treatment liquid according to claim 1, wherein the treatment liquid is a developer or a rinsing liquid.

18. The method for inspecting a treatment liquid according to claim 1, wherein the treatment liquid is used for treatment of a resist composition to be exposed with KrF, ArF, ArF liquid immersion, extreme ultraviolet rays, or an electron beam.

19. A method for producing a treatment liquid, comprising the method for inspecting a treatment liquid according to claim 1.

20. The method for inspecting a treatment liquid according to claim 2, wherein the aliphatic hydrocarbon solvent is undecane.
